(19) United States
(12) Patent Application Publication
(10) Pub. No.: US 2023/0317421 A1
(43) Pub. Date: Oct. 5, 2023

(54) PLASMA PROCESSING APPARATUS

(71) Applicant: Tokyo Electron Limited, Tokyo (JP)

(72) Inventors: Takafumi NOGAMI, Nirasaki City (JP); Kenichi KOTE, Nirasaki City (JP)

(21) Appl. No.: 18/125,322

(22) Filed: Mar. 23, 2023

(30) Foreign Application Priority Data
Mar. 30, 2022 (JP) 2022-057367

(51) Int. Cl. H01J 37/32; C23C 16/458; C23C 16/511; C23C 16/455; C23C 16/34

(52) U.S. Cl. CPC H01J 37/32449; H01J 37/32238; C23C 16/4583; C23C 16/511; C23C 16/45565; C23C 16/345; H01J 2237/332

(57) ABSTRACT

A plasma processing apparatus includes: a stage on which a substrate is placed; a chamber in which the stage is provided; a plasma source configured to introduce a microwave into the chamber from a ceiling wall of the chamber so as to generate surface wave plasma inside the chamber; and at least one gas discharger configured to discharge a gas toward the stage. The at least one gas discharger is configured to adjust a gas discharge position in a predetermined plane and a distance from a center of the stage to the gas discharge position by changing a gas supply path existing inside the at least one gas discharger.

### CROSS-REFERENCE TO RELATED APPLICATION

This application is based upon and claims the benefit of priority from Japanese Patent Application No. 2022-057367, filed on Mar. 30, 2022, the entire contents of which are incorporated herein by reference.

### TECHNICAL FIELD

The present disclosure relates to a plasma processing apparatus.

### BACKGROUND

A plasma processing apparatus disclosed in Patent Document 1 includes a chamber, a stage, and a plasma source that introduces a microwave into a chamber through a ceiling wall of the chamber and generates surface wave plasma inside the chamber. The above plasma processing apparatus further includes a first gas shower part that supplies a first gas into the chamber from the ceiling wall, and a second gas shower part that introduces a second gas into the chamber from between the ceiling wall and the stage. The second gas shower part extends from the ceiling wall toward the stage and includes a plurality of nozzles arranged at equal intervals on the same circumference. Each of the plurality of nozzles discharges the second gas toward adjacent nozzles.

### PRIOR ART DOCUMENT

### Patent Document

Patent Document 1: Japanese Laid-Open Patent Publication No. 2018-73880

### SUMMARY

According to one embodiment of the present disclosure, there is provided a plasma processing apparatus includes: a stage on which a substrate is placed; a chamber in which the stage is provided; a plasma source configured to introduce a microwave into the chamber from a ceiling wall of the chamber so as to generate surface wave plasma inside the chamber; and at least one gas discharger configured to discharge a gas toward the stage. The at least one gas discharger is configured to adjust a gas discharge position in a predetermined plane and a distance from a center of the stage to the gas discharge position by changing a gas supply path existing inside the at least one gas discharger.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view showing a schematic configuration of a film forming apparatus as a plasma processing apparatus according to a first embodiment.

FIG. 2 is a block diagram showing a configuration of a microwave plasma source used in the plasma processing apparatus of FIG. 1.

FIG. 3 is a view showing an arrangement of a microwave radiation mechanism in the microwave plasma source of FIG. 2.

FIG. 4 is a cross-sectional view showing the microwave radiation mechanism in the microwave plasma source of the plasma processing apparatus of FIG. 1.

FIG. 5 is a bottom view of a ceiling wall.

FIG. 6 is a partially enlarged cross-sectional view for explaining an outline of a gas discharger of a second gas shower part.

FIG. 7 is a partially enlarged cross-sectional view for explaining an outline of the gas discharger of the second gas shower part.

FIG. 8 is a partially enlarged cross-sectional view for explaining an outline of the gas discharger of the second gas shower part.

FIG. 9 is a partially enlarged cross-sectional view for explaining an outline of the gas discharger of the second gas shower part.

FIG. 10 is a view for explaining an outline of a nozzle of a third gas shower part.

FIG. 11 is a diagram showing a thickness distribution of a SiN film formed using a film forming apparatus in the related art.

FIG. 12 is a diagram showing a refractive index distribution of the SiN film formed using the film forming apparatus in the related art.

FIG. 13 is a diagram showing a thickness distribution of a SiN film formed using the film forming apparatus of FIG. 1.

FIG. 14 is a diagram showing a refractive index distribution of the SiN film formed using the film forming apparatus of FIG. 1.

FIG. 15 is a table showing a difference between maximum and minimum values of film thickness and refractive index in a wafer in-plane of the SiN film formed using the film forming apparatus of FIG. 1.

FIG. 16 is a table showing a difference between maximum and minimum values of film thickness and refractive index in the wafer in-plane of the SiN film formed using the film forming apparatus of FIG. 1.

FIG. 17 is a partially enlarged cross-sectional view for explaining an outline of a gas discharger of a second gas shower part of a film forming apparatus as a plasma processing apparatus according to a second embodiment.

FIG. 18 is a bottom view for explaining an outline of the gas discharger of the second gas shower part of the film forming apparatus as the plasma processing apparatus according to the second embodiment.

FIG. 19 is a partially enlarged cross-sectional view for explaining an outline of a gas discharger of a second gas shower part of a film forming apparatus as a plasma processing apparatus according to a third embodiment.

FIG. 20 is a partially enlarged cross-sectional view for explaining an outline of a gas discharger of a first gas shower part of a film forming apparatus as a plasma processing apparatus according to a fourth embodiment.

FIG. 21 is a partially enlarged cross-sectional view for explaining an outline of the gas discharger of the first gas shower part of the film forming apparatus as the plasma processing apparatus according to the fourth embodiment.

FIG. 22 is a partially enlarged cross-sectional view for explaining an outline of the gas discharger of the first gas shower part of the film forming apparatus as the plasma processing apparatus according to the fourth embodiment.

FIG. 23 is a partially enlarged cross-sectional view for explaining an outline of the gas discharger of the first gas shower part of the film forming apparatus as the plasma processing apparatus according to the fourth embodiment.

FIG. 24 is a partially enlarged cross-sectional view for explaining an outline of a gas discharger of a first gas shower part of a film forming apparatus as a plasma processing apparatus according to a fifth embodiment.

FIG. 25 is a partially enlarged cross-sectional view for explaining an outline of a gas discharger of a first gas shower part of a film forming apparatus as a plasma processing apparatus according to a sixth embodiment.

FIG. 26 is a partially enlarged cross-sectional view for explaining an outline of a gas discharger of a third gas shower part of a film forming apparatus as a plasma processing apparatus according to a seventh embodiment.

FIG. 27 is a partially enlarged cross-sectional view for explaining an outline of the gas discharger of the third gas shower part of the film forming apparatus as the plasma processing apparatus according to the seventh embodiment.

FIG. 28 is a partially enlarged cross-sectional view for explaining an outline of the gas discharger of the third gas shower part of the film forming apparatus as the plasma processing apparatus according to the seventh embodiment.

FIG. 29 is a partially enlarged cross-sectional view for explaining an outline of the gas discharger of the third gas shower part of the film forming apparatus as the plasma processing apparatus according to the seventh embodiment.

FIG. 30 is a partially enlarged cross-sectional view for explaining an outline of a gas discharger of a third gas shower part of a film forming apparatus as a plasma processing apparatus according to an eighth embodiment.

FIG. 31 is a partially enlarged cross-sectional view for explaining the outline of a gas discharger of a third gas shower part of a film forming apparatus as a plasma processing apparatus according to a ninth embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a process of manufacturing a semiconductor device and the like, a plasma process is performed on a substrate such as a semiconductor wafer (hereinafter referred to as a “wafer W”). As a plasma processing apparatus for performing a plasma process, there is known one that uses a microwave capable of generating high-density and low-electron temperature surface wave plasma (see Patent Document 1).

In a plasma processing apparatus using a microwave, for example, a gas is supplied into a chamber from the following three locations.
Directly from a ceiling wall of the chamber.
From a nozzle extending from the ceiling wall toward a stage on which a substrate is placed inside the chamber.
From a nozzle extending from a sidewall of the chamber.

When the plasma process is a film forming process, a material gas that directly contributes to film formation is supplied from, for example, the two types of nozzles described above. When the substrate in-plane uniformities of the thickness and refractive index of a film formed by the plasma process are required, these uniformities may be achieved by adjusting the balance of material gas flow rates among nozzle types. However, depending on an internal pressure of the chamber, at least one of the film thickness and the refractive index may become non-uniform in the radial direction of the substrate even if the balance is adjusted as described above. Moreover, since the internal pressure of the chamber is determined by the target film quality (specifically, a film stress), it is not preferable to change it significantly.

Thus, the plasma process using the microwave has room for improvement in the uniformity of the substrate in the radial direction.

Therefore, the technique according to the present disclosure improves the uniformity of plasma processing results in the radial direction of a substrate in a plasma processing apparatus that uses a microwave, without changing the processing conditions that are not desirable to change.

A plasma processing apparatus according to embodiments of the present disclosure will now be described with reference to the drawings. Throughout the present disclosure and the drawings, elements having substantially the same functional configuration will be denoted by the same reference numerals, and therefore, description thereof will not be repeated.

### First Embodiment

### <Film Forming Apparatus>

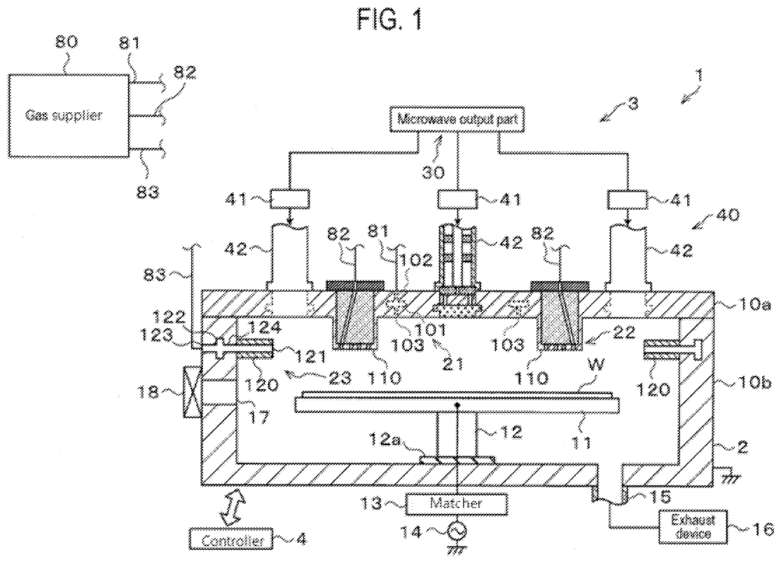

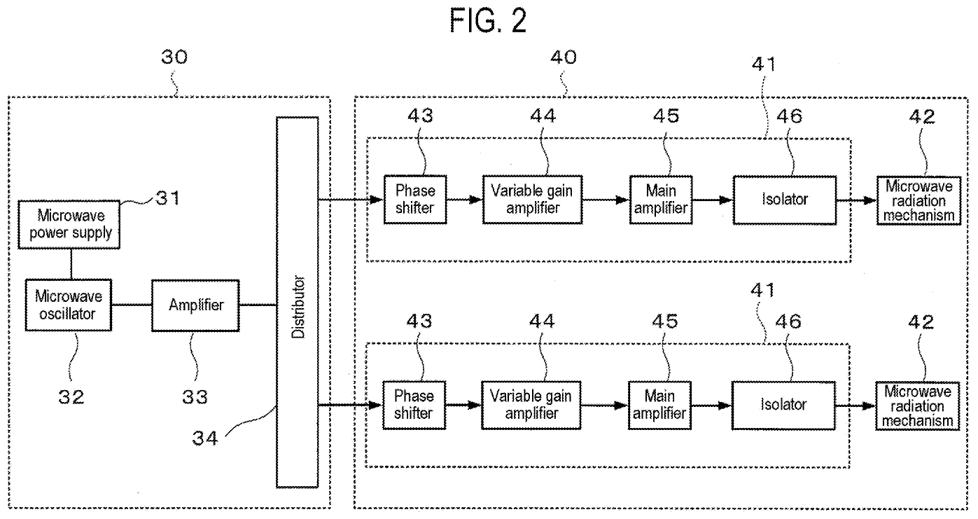

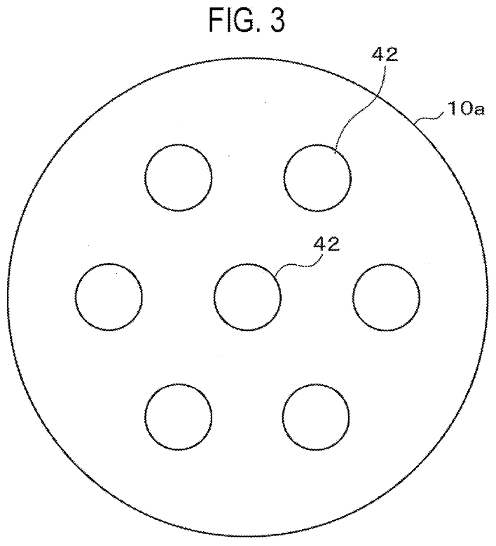

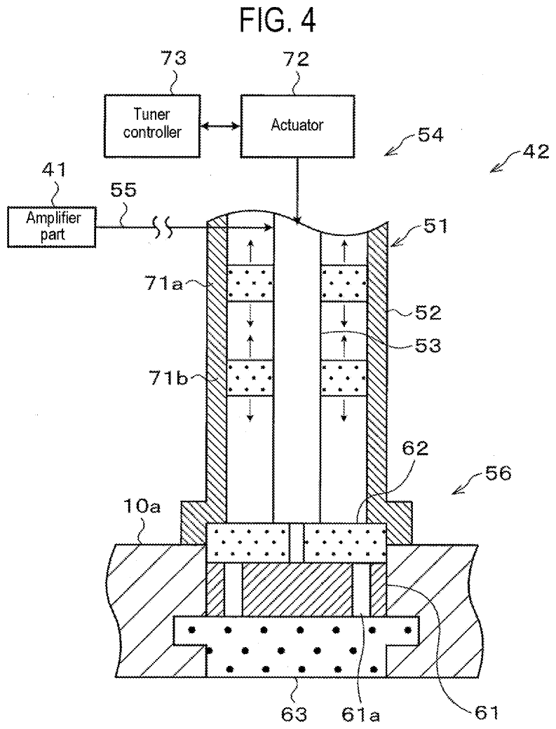

FIG. 1 is a cross-sectional view showing a schematic configuration of a film forming apparatus as a plasma processing apparatus according to a first embodiment. FIG. 2 is a block diagram showing a configuration of a microwave plasma source used in the plasma processing apparatus of FIG. 1. FIG. 3 is a view showing an arrangement of a microwave radiation mechanism in the microwave plasma source of FIG. 2, and FIG. 4 is a cross-sectional view showing the microwave radiation mechanism in the microwave plasma source of the plasma processing apparatus of FIG. 1.

The film forming apparatus 1 of FIG. 1 forms surface wave plasma using a microwave and performs a film forming process as a plasma process on a wafer W as a substrate.

The film forming apparatus 1 includes a chamber 2 and a microwave plasma source 3. A susceptor 11 as a stage on which the wafer W is placed is provided inside the chamber 2. The microwave plasma source 3 introduces a microwave into the chamber 2 from a ceiling wall 10a of the chamber 2 so as to generate the surface wave plasma inside the chamber 2.

The chamber 2 is configured to be airtight and is made of, for example, a metal material such as aluminum in substantially a cylindrical shape. Also, the chamber 2 is grounded.

The ceiling wall 10a of the chamber 2 is formed in a disc shape and is formed by fitting dielectric members of a plurality of microwave radiation mechanisms which will be described later, into a main body portion made of metal. The microwave plasma source 3 introduces the microwave into the chamber 2 via the plurality of dielectric members of the ceiling wall 10a.

A portion of an inner wall surface of the chamber 2 that is exposed to plasma is thermally sprayed with ceramics such as Y₂O₃. A chamber base material (for example, aluminum) may be exposed on other portions of the inner wall surface of the chamber 2.

The film forming apparatus 1 also includes a controller 4. The controller 4 is, for example, a computer provided with a processor such as a CPU, and a memory and includes a program storage part (not shown). A program for controlling the processing of the wafer W in the film forming apparatus 1 is stored in the program storage part. The program may be recorded in, for example, a computer-readable storage medium and may be installed in the controller 4 from the storage medium. The storage medium may be transitory or non-transitory.

Inside the chamber 2, the above-mentioned susceptor 11 is provided in a state of being supported by a cylindrical support member 12 erected at the center of the bottom of the chamber 2 via an insulating member 12a. The susceptor 11 and the support member 12 are made of, for example, a metal material such as aluminum in a disc shape, and the surfaces thereof are alumite-treated (anodized).

The susceptor 11 may be provided with a temperature control mechanism for the wafer W, a gas flow path for supplying a heat transfer gas to the back surface of the wafer W, an electrostatic chuck for electrostatically sucking the wafer W, and the like. Lift pins that moves up and down in order to transfer the wafer W to/from the susceptor 11 is provided for the susceptor 11.

Further, a radio-frequency bias power supply 14 is electrically connected to the susceptor 11 via a matcher 13. Ions in plasma are drawn toward the wafer W by supplying radio-frequency power from the radio-frequency bias power supply 14 to the susceptor 11. The susceptor 11 may be constructed of an insulating member having therein an electrode to which radio-frequency power is supplied from the radio-frequency bias power supply 14. Further, the radio-frequency bias power supply 14 may be omitted depending on the characteristics of plasma process. In this case, electrodes are unnecessary even if the susceptor 11 is made of an insulating material.

An exhaust pipe 15 is connected to the side of the bottom of the chamber 2, and an exhaust device 16 including a vacuum pump is connected to the exhaust pipe 15. By operating the exhaust device 16, the interior of the chamber 2 may be exhausted, so that the interior of the chamber 2 may be decompressed and set to have a predetermined pressure. A loading/unloading port 17 for loading/unloading the wafer W therethrough and a gate valve 18 for opening/closing the loading/unloading port 17 are provided in a sidewall 10b of the chamber 2.

The film forming apparatus 1 also includes a first gas shower part 21 as an upper gas supplier that supplies a gas from the ceiling wall 10a of the chamber 2 into the chamber 2, and a second gas shower part 22 as an intermediate gas supplier that supplies a gas at a predetermined height between the ceiling wall 10a and the susceptor 11. Further, the film forming apparatus 1 includes a third gas shower part 23 as a lateral gas supplier that supplies a gas into the chamber 2 from a lateral side of the susceptor 11. Specifically, the third gas shower part 23 introduces a gas into the chamber 2 from a position between the ceiling wall 10a and the susceptor 11 inside the chamber 2 and outside a supply position by the second gas shower part 22. Details of the first to third gas shower parts 21 to 23 will be described later.

Among the gases supplied into the chamber 2, a material gas is not supplied from, for example, the first gas shower part 21, but is supplied from the second and third gas shower parts 22 and 23. A plasma excitation gas such as Ar or He is supplied from, for example, the first and third gas shower parts 21 and 23. In this case, the plasma excitation gas may or may not be supplied from the second gas shower part 22. When the film formation target is a nitride film, a nitriding gas such as a N₂ gas or an NH₃ gas is supplied from, for example, the first and third gas shower parts 21 and 23. Also in this case, the nitriding gas may or may not be supplied from the second gas shower part 22.

When the film formation target is a SiN film, the material gas is, for example, a SiH₄ gas, and when the film formation target is a SiC film or a SiCN film, the material gas is, for example, a SiH₄ gas or a C₂H₆ gas.

The microwave plasma source 3 includes a microwave output part 30 that outputs a microwave to a plurality of distributed paths, and a microwave transmission part 40 that transmits the microwave output from the microwave output part 30.

As shown in FIG. 2, the microwave output part 30 includes a microwave power supply 31, a microwave oscillator 32, an amplifier 33, and a distributor 34.

The microwave power supply 31 supplies power to the microwave oscillator 32. The microwave oscillator 32 oscillates a microwave having a predetermined frequency (for example, 860 MHz) by, for example, a phase locked loop (PLL) manner. The amplifier 33 amplifies the oscillated microwave. The distributor 34 distributes the microwave amplified by the amplifier 33 while matching the impedances of the input side and the output side so as to minimize a microwave loss. In addition to 860 MHz, various frequencies in a range from 700 MHz to 3 GHz, such as 915 MHz, may be used as the microwave frequency.

The microwave transmission part 40 includes a plurality of amplifier parts 41 and a plurality of microwave radiation mechanisms 42 provided to correspond to the amplifier parts 41. For example, as shown in FIG. 3, one microwave radiation mechanism 42 is provided at the center of the ceiling wall 10a, and a plurality of microwave radiation mechanisms 42 are arranged along the circumferential direction around the central one. More specifically, one microwave radiation mechanism 42 is arranged in the center of the ceiling wall 10a, and six microwave radiation mechanisms 42 are arranged at equal intervals on the same circumference around the center one, for a total of seven microwave radiation mechanisms. In this example, these are arranged so that a distance between the central microwave radiation mechanism 42 and the outer peripheral microwave radiation mechanisms 42 is equal to a distance between the outer peripheral microwave radiation mechanisms 42.

Each amplifier part 41 of the microwave transmission part 40 guides the microwave distributed by the distributor 34 to the respective microwave radiation mechanism 42. The amplifier part 41 includes a phase shifter 43, a variable gain amplifier 44, a main amplifier 45, and an isolator 46.

The phase shifter 43 is configured to change a phase of the microwave and may modulate the radiation characteristics by adjusting the phase of the microwave. For example, by adjusting the phase for each microwave radiation mechanism 42, the phase shifter 43 may control the directivity to change a plasma distribution. Further, the phase shifter 43 may obtain a circularly-polarized wave by shifting the phase by 90 degrees in the adjacent microwave radiation mechanisms 42. Further, the phase shifter 43 may be used for the purpose of spatial synthesis within a tuner, which will be described later, by adjusting delay characteristics between components within amplifiers. However, the phase shifter 43 may be omitted when such modulation of radiation characteristics and adjustment of delay characteristics between components within the amplifiers are unnecessary.

The variable gain amplifier 44 is an amplifier for adjusting a power level of the microwave input to the main amplifier 45 to adjust the plasma intensity. By changing the variable gain amplifier 44 for each amplifier part 41, the generated plasma may be distributed.

The main amplifier 45 constitutes a solid-state amplifier and may have, for example, an input matching circuit, a semiconductor amplifying element, an output matching circuit, and a high-Q resonance circuit.

The isolator 46 separates a reflected microwave reflected by a planar antenna, which will be described later, toward the main amplifier 45, and includes a circulator and a dummy load (coaxial terminator). The circulator guides the reflected microwave to the dummy load in which the reflected microwave guided by the circulator is converted into heat.

The microwave radiation mechanism 42 has a function of radiating the microwave output from the amplifier part 41 into the chamber 2 and a function of matching the impedance.

The microwave radiation mechanism 42 includes a coaxial tube 51, as shown in FIG. 4. The coaxial tube 51 includes a coaxial microwave transmission line composed of a tubular outer conductor 52 and a rod-shaped inner conductor 53 provided at the center of the outer conductor 52. The microwave radiation mechanism 42 also includes a feeding antenna (not shown) that feeds the microwave amplified by the amplifier part 41 to the coaxial tube 51 via a coaxial cable 55. Further, the microwave radiation mechanism 42 includes a tuner 54 that matches the impedance of a load with the characteristic impedance of the microwave power supply 31, and an antenna part 56 that radiates the microwave from the coaxial tube 51 into the chamber 2.

The microwave fed from the side of the upper end portion of the outer conductor 52 by the coaxial cable 55 is radiated from the feeding antenna, and microwave power is fed to the microwave transmission line between the outer conductor 52 and the inner conductor 53 and propagates toward the antenna part 56.

The antenna part 56 is provided at the lower end portion of the coaxial tube 51 and is fitted into a metal portion of the ceiling wall 10a of the chamber 2. The antenna part 56 includes a disk-shaped planar antenna 61 connected to the lower end portion of the inner conductor 53, a slow-wave material 62 disposed on the upper surface side of the planar antenna 61, and a dielectric window 63 disposed on the lower surface side of the planar antenna 61.

A slot 61a is formed to penetrate through the planar antenna 61 in its thickness direction. The slot 61a has a shape so that the microwave is efficiently radiated. A dielectric may be inserted into the slot 61a.

The slow-wave material 62 is made of a dielectric having a dielectric constant greater than that of vacuum and has a function of shortening the wavelength of the microwave to reduce the size of antenna. The slow-wave material 62 may adjust the phase of the microwave by its thickness. By adjusting the thickness of the slow-wave material 62 so that a junction portion of the planar antenna 61 becomes the “antinode” of a standing wave, the radiation energy of the microwave may be maximized.

The dielectric window 63 is also made of a similar dielectric and is fitted into a metal portion of the ceiling wall 10a, and its lower surface is exposed to the internal space of the chamber 2. The dielectric window 63 has a shape to allow efficient radiation of the microwave in a TF mode. Then, the microwave transmitted through the dielectric window 63 generates surface wave plasma in a portion directly below the dielectric window 63 inside the chamber 2.

In the following description, among dielectric windows 63, a dielectric window provided at the center is referred to as a central dielectric window 63, and a plurality of dielectric windows provided along the circumferential direction around the central dielectric window 63 are referred to as outer dielectric windows 63. Specifically, six outer dielectric windows 63 are provided at equal intervals on the same circumference around the central dielectric window 63.

The slow-wave material 62 and the dielectric window 63 are made of, for example, quartz, ceramics, fluorine-based resin such as polytetrafluoroethylene resin, polyimide resin, or the like.

The tuner 54 includes two slugs 71a and 71b arranged at a portion closer to the base end portion side (upper end portion side) than the antenna part 56 of the coaxial tube 51 and constitutes a slug tuner. The tuner 54 also includes an actuator 72 that drives these two slugs independently, and a tuner controller 73 that controls the actuator 72.

The slugs 71a and 71b are made of a dielectric material such as ceramics, have a plate-like and annular shape, and are arranged between the outer conductor 52 and the inner conductor 53 of the coaxial tube 51. The actuator 72 individually drives the slugs 71a and 71b by, for example, rotating two screws provided inside the inner conductor 53, with which the slugs 71a and 71b are screwed respectively. The actuator 72 vertically moves the slugs 71a and 71b based on a command from the tuner controller 73. When only one of the two slugs 71a and 71b is moved, a trajectory which passes through the origin of the Smith chart is drawn, and when both are moved simultaneously, only the phase rotates. The tuner controller 73 performs impedance matching by controlling the positions of the slugs 71a and 71b so that the impedance of the peripheral end portion becomes 50Ω.

The main amplifier 45, the tuner 54, and the planar antenna 61 are arranged close to each other. The tuner 54 and the planar antenna 61 form a lumped constant circuit and function as a resonator. Although there is an impedance mismatch at an attachment portion of the planar antenna 61, since the tuner 54 directly tunes the plasma load, it is possible to tune the plasma load with high precision, resolving the effect of reflection on the planar antenna 61.

### <First to Third Gas Shower Parts 21 to 23>

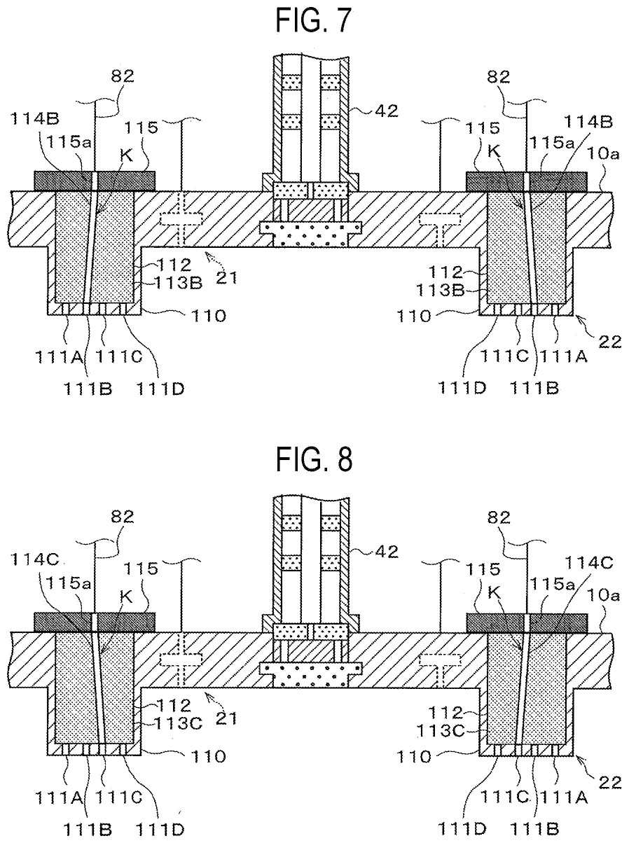

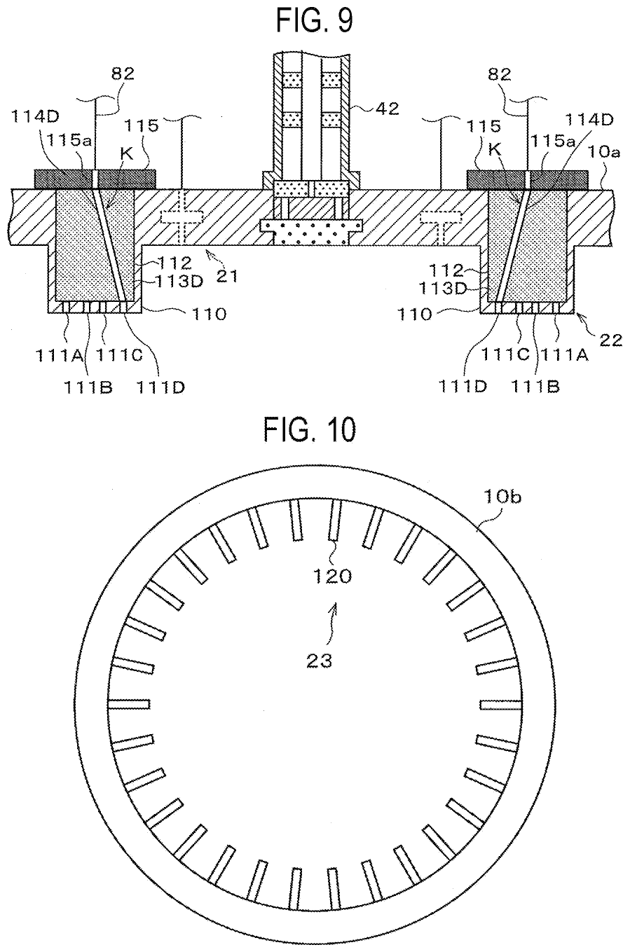

Next, the first to third gas shower parts 21 to 23 will be described with reference to FIGS. 1 and 5 to 10.

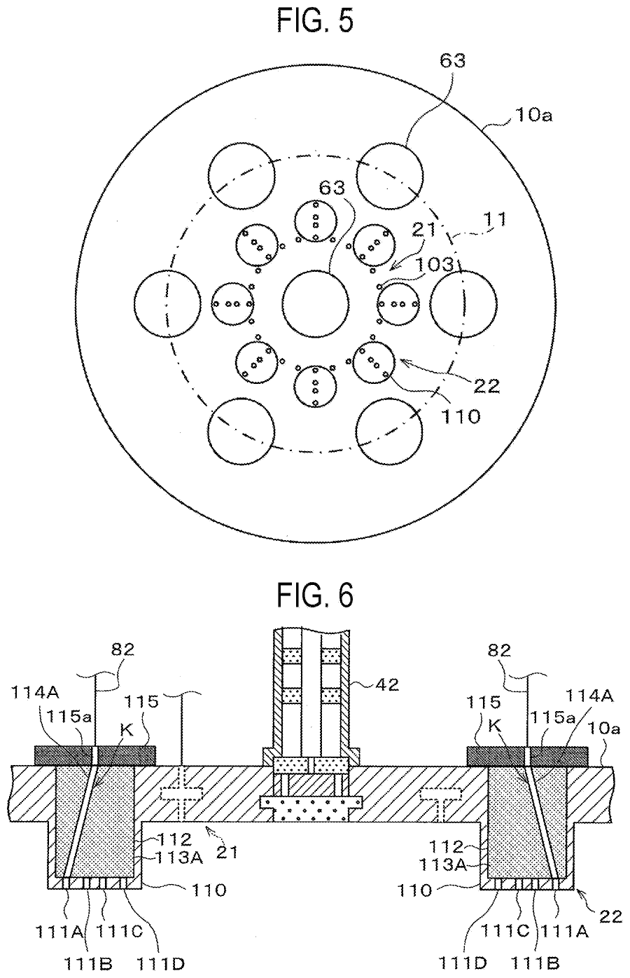

FIG. 5 is a bottom view of the ceiling wall 10a. FIGS. 6 to 9 are partially enlarged cross-sectional views for explaining the outline of a gas discharger (which will be described later) of the second gas shower part 22. FIG. 10 is a view for explaining an outline of a nozzle (which will be described later) of the third gas shower part 23 and is a plan view of the sidewall 10b on which the third gas shower part 23 is provided.

The film forming apparatus 1 includes the first to third gas shower parts 21 to 23, as shown in FIG. 1. The first gas shower part 21 supplies a gas from the ceiling wall 10a of the chamber 2 toward the susceptor 11 (specifically, downward). The second gas shower part 22 supplies a gas toward the susceptor 11 (specifically, downward) at a predetermined height between the ceiling wall 10a and the susceptor 11. The third gas shower part 23 supplies a gas toward the susceptor 11 (specifically, horizontally) at a position between the ceiling wall 10a and the susceptor 11 in the chamber 2 and outside a discharge position of the second gas shower part 22.

The first gas shower part 21 includes, for example, a diffusion space 101 formed in an annular shape around the susceptor 11 inside the metal portion of the ceiling wall 10a, and an introduction hole 102 that is provided above the diffusion space 101 and communicates with the diffusion space 101. The first gas shower part 21 also includes a plurality of discharge holes 103 extending from the diffusion space 101 to the internal space of the chamber 2. One end of a pipe 81 is connected to the introduction hole 102. The other end of the pipe 81 is connected to a gas supplier 80. The gas supplier 80 includes various gas sources and the like. Therefore, a gas from the gas supplier 80 is discharged from the discharge holes 103 toward the susceptor 11 (specifically, downward) through the pipe 81, the introduction hole 102, and the diffusion space 101. As shown in FIG. 5, the plurality of discharge holes 103 are provided on the same circumference around the center of the ceiling wall 10a (that is, the center of the susceptor 11) in a plan view. Further, the discharge holes 103 are provided so that the distribution of the gas discharged from the discharge holes 103 is uniform. A distance from the center of the susceptor 11 to each discharge hole 103 (that is, each discharge position of the first gas shower part 21) in a plan view is, for example, 80 mm.

The second gas shower part 22 includes a gas discharger 110, as shown in FIGS. 1 to 5. The gas discharger 110 discharges a gas toward the susceptor 11. A plurality of gas dischargers 110 may be provided along the circumferential direction of the ceiling wall 10a (that is, the circumferential direction of the susceptor 11) in a plan view. More specifically, the plurality of gas dischargers 110 (eight gas dischargers 110 in the example shown) are arranged at equal intervals on the same circumference around the center of the ceiling wall 10a (that is, the center of the susceptor 11) in a plan view.

Each gas discharger 110 is connected to one end of the pipe 82. The other end of the pipe 82 is connected to the gas supplier 80 (see FIG. 1).

Each gas discharger 110 includes a gas supply path K provided therein to guide a gas to a discharge position, that is, a discharge port, of the gas from the gas discharger 110. Further, by changing the gas supply path K, each gas discharger 110 is configured such that the discharge position in a predetermined plane and a distance from the center of the susceptor 11 to the discharge position may be adjusted. Specifically, each gas discharger 110 is configured to be able to adjust the discharge position in the horizontal plane in the radial direction of the susceptor 11 (hereinafter referred to as a susceptor radial direction) by changing the gas supply path K.

Further, each gas discharger 110 is configured to be able to selectively discharge a gas from a plurality of discharge positions having different distances from the center of the susceptor 11. Specifically, each gas discharger 110 is configured to be able to selectively discharge a gas from a plurality of discharge positions (four discharge positions in this example) that are different from each other in the horizontal plane in the susceptor radial direction.

In the present embodiment, each gas discharger 110 includes discharge holes 111A to 111D. Hereinafter, the discharge holes 111A to 111D may be abbreviated as the discharge hole 111.

The discharge hole 111 is provided for each discharge position of the gas from the gas discharger 110 so as to correspond to the discharge position. The discharge holes 111 are arranged, for example, in the horizontal plane in the susceptor radial direction.

The gas discharger 110 is formed such that its lower portion protrudes downward from the lower surface of the ceiling wall 10a. The discharge hole 111 is formed at the lower end of the gas discharger 110. A portion of the gas discharger 110 protruding downward from the lower surface of the ceiling wall 10a has, for example, a cylindrical shape.

Distances from the center of the susceptor 11 to the discharge holes 111A, 111B, 111C, and 111D in a plan view are, for example, 105 mm, 95 mm, 90 mm, and 80 mm, respectively.

Further, each gas discharger 110 includes a recess 112 communicating with each of the discharge holes 111A to 111D. The recess 112 is formed, for example, so as to be cylindrically depressed downward from the upper surface of the ceiling wall 10a.

As shown in FIGS. 6 to 9, any one of flow path members 113A to 113D may be inserted into and removed from the recess 112. Hereinafter, the flow path members 113A to 113D may be abbreviated as the flow path member 113, and flow paths 114A to 114D, which will be described later, may be abbreviated as a flow path 114.

The flow path member 113A forms the flow path 114A whose downstream end, that is, lower end, is connected only to the discharge hole 111A.

The flow path member 113B forms the flow path 114B whose downstream end, that is, lower end, is connected only to the discharge hole 111B.

The flow path member 113C forms the flow path 114C whose downstream end, that is, lower end, is connected only to the discharge hole 111C.

The flow path member 113D forms the flow path 114D whose downstream end, that is, lower end, is connected only to the discharge hole 111D.

The gas discharger 110 includes the flow path member 113 that forms the flow path 114 arranged inside the recess 112 and connected to one of the discharge holes 111. Further, the flow path members 113A to 113D are selectively used. The flow path member 113 is made of, for example, a metal material such as aluminum and formed in a columnar shape.

Further, a mark (not shown) serving as a guide for the orientation of the flow path members 113A to 113D may be formed on, for example, the tops of the flow path members 113A to 113D so that the flow path members 113A to 113D may be arranged inside the recess 112 in a desired orientation.

Further, each gas discharger 110 includes a lid member 115 that closes an opening portion of the recess 112. The flow path member 113 may be pressed from above by the lid member 115 to bring the flow path member 113 and the bottom of the recess 112 into close contact with each other.

A sealing member (not shown) such as an O-ring for sealing the chamber 2 is provided between the lid member 115 and the upper surface of the ceiling wall 10a.

The lid member 115 includes an introduction hole 115a for introducing a gas into the flow path of the flow path member 113. The introduction hole 115a communicates with the interior of the recess 112 when the lid member 115 is attached to the ceiling wall 10a, and is connected to the upstream end, that is, the upper end, of the flow path 114 of the flow path member 113 arranged within the recess 112. In the present embodiment, the introduction hole 115a is connected to one end of the above-mentioned pipe 82. The other end of the pipe 82 is connected to the gas supplier 80, as described above. Therefore, the gas from the gas supplier 80 is discharged from the discharge hole 111 corresponding to the flow path member 113 toward the susceptor 11 (specifically, downward) through the pipe 82, the introduction hole 115a, and the flow path 114 of one of the flow path members 113 arranged inside the recess 112.

As described above, each gas discharger 110 is configured to be able to adjust the gas discharge position in the horizontal plane in the susceptor radial direction by changing the gas supply path K. In the present embodiment, changing the gas supply path K means changing the flow path member 113 arranged inside the recess 112, and each gas discharger 110 selectively discharges a gas from the discharge hole 111 corresponding to the flow path member 113 arranged inside the recess 112. For example, when the flow path member 113A is used, each gas discharger 110 selectively discharges the gas from the discharge hole 111A corresponding to the flow path member 113A.

The dimensions of the gas discharger 110 are, for example, as follows.
The outer diameter of the columnar portion protruding downward from the lower surface of the ceiling wall 10a in the gas discharger 110 is 35 to 45 mm
The inner diameter of the recess 112 and the outer diameter of the flow path member 113 is 30 to 35 mm
The diameter of the discharge hole 111 is 0.3 mm

A gap between the lower surface of the flow path member 113 and the bottom of the recess 112 is, for example, 0.01 mm or less. By narrowing the gap in this way, a gas may be prevented from being discharged from discharge holes other than the discharge hole 111 corresponding to the flow path member 113 arranged inside the recess 112.

Further, a gap between the side surface of the flow path member 113 and the inner side surface of the recess 112 may be set to, for example, 0.01 mm or less. As a result, when the gas is a corrosive gas, damage to the O-ring arranged between the lid member 115 and the ceiling wall 10a may be suppressed.

Furthermore, by reducing the gap between the flow path member 113 and the recess 112 as described above, it is possible to suppress the occurrence of abnormal discharge in the gap.

The third gas shower part 23 includes a nozzle 120, as shown in FIGS. 1 and 10. The nozzle 120 horizontally extends from the sidewall 10b toward the center of the chamber 2 in a plan view. A plurality of nozzles 120 are provided along the annular sidewall 10b. In other words, the plurality of nozzles 120 are provided along the circumferential direction of the ceiling wall 10a (that is, the circumferential direction of the susceptor 11) in a plan view. More specifically, the plurality of nozzles 120 (30 nozzles in the example shown) are arranged at equal intervals on the same circumference around the center of the ceiling wall 10a (that is, the center of the susceptor 11) in a plan view. Further, each nozzle 120 is formed in a region that does not overlap the wafer W in a plan view.

Each nozzle 120 is formed in a tubular shape (specifically, a cylindrical shape), and a hollow portion of the tubular shape serves as a discharge hole 121 through which a gas is discharged toward the center of the chamber 2 in a plan view.

Further, the third gas shower part 23 has an annular diffusion space 122 formed in the sidewall 10b and an introduction hole 123 provided outside the diffusion space 122 and communicating with the diffusion space 122. The third gas shower part 23 also includes a flow path 124 extending from the diffusion space 122 to the nozzle 120. One end of a pipe 83 is connected to the above-mentioned introduction hole 123. The other end of the pipe 83 is connected to the gas supplier 80. Therefore, a gas from the gas supplier 80 reaches the nozzle 120 through the pipe 83, the introduction hole 123, and the diffusion space 122, and is discharged from the discharge hole 121 toward the center of the chamber 2 in a plan view.

In the present embodiment, the material gas is supplied not only from the third gas shower part 23 but also from the second gas shower part 22. If the material gas is supplied only from the third gas shower part 23, it is difficult for the material gas to reach the central portion of the wafer W placed on the susceptor 11. However, by supplying the material gas from the second gas shower part 22 as well, the density of the material gas may be increased even in the central portion of the wafer W.

### <Wafer Processing>

Next, wafer processing performed using the film forming apparatus 1 will be described with an example of forming a SiN film. This wafer processing is performed under the control of the controller 4.

First, the wafer W is loaded into the chamber 2 and is placed on the susceptor 11.

Subsequently, the interior of the chamber 2 is exhausted by the exhaust device 16 and is adjusted to a predetermined pressure.

Thereafter, various gases are discharged into the chamber 2, and a microwave is emitted into the chamber 2. A film forming process is performed on the wafer W with plasma generated by the microwave to form a SiN film on the wafer W. During this film forming process, the interior of the chamber 2 is continuously exhausted by the exhaust device 16 and is adjusted to a desired pressure (hereinafter referred to as a film formation pressure). The film formation pressure is determined, for example, according to target properties of the SiN film to be formed. Specifically, for example, when a film stress of the SiN film to be formed is targeted to be a tensile stress, the film formation pressure is set to 20 Pa, and in other cases to 10 Pa.

During the film forming process, an Ar gas as an excitation gas and an NH₃ gas as a nitriding gas are supplied from the gas supplier 80 to the first gas shower part 21 through the pipe 81 and are discharged from the first gas shower part 21 into the chamber 2.

Further, a SiH₄ gas as a material gas is supplied from the gas supplier 80 to the second and third gas shower parts 22 and 23 through the pipes 82 and 83, respectively, and is discharged from these second and third gas shower parts 22 and 23 into the chamber 2.

Further, during the film forming process, a microwave transmitted from the microwave output part 30 of the microwave plasma source 3 through the transmission paths of the plurality of amplifier parts 41 and the plurality of microwave radiation mechanisms 42 of the microwave transmission part 40 is radiated into the chamber 2 via the slow-wave material 62 of the antenna part 56, the slot 61a of the planar antenna 61, and the dielectric window 63. At this time, the impedance is automatically matched by the slug 71a and the slug 71b of the tuner 54, and the microwave is supplied with substantially no power reflection. The microwave radiated from each microwave radiating mechanism 42 is spatially combined to form a microwave electric field and generate surface wave plasma of the Ar gas inside the chamber 2.

The generated surface wave plasma dissociates the NH₃ gas from the first gas shower part 21 and the SiH₄ gas from the second and third gas shower parts 22 and 23 to be plasmarized. A SiN film is formed on the wafer W by the plasma of the NH₃ gas and the SiH₄ gas.

Further, during the film forming process, among the flow path members 113A to 113D, the flow path member 113 determined in advance according to the film formation pressure by experiments, simulations, or the like is arranged inside the recess 112 of each gas discharger 110 of the second gas shower part 22. That is, during the film forming process, the discharge of the SiH₄ gas from the second gas shower part 22 is performed from a discharge position in the horizontal plane in the susceptor radial direction, which is determined in advance according to the film formation pressure.

The electron temperature of the surface wave plasma of the Ar gas is high in the vicinity of the lower surface of the ceiling wall 10a and decreases as a distance from the lower surface of the ceiling wall 10a increases to approach the susceptor 11. Therefore, a N₂ gas discharged directly from the first gas shower part 21, that is, from the lower surface of the ceiling wall 10a, is dissociated with high energy. In contrast, the SiH₄ gas discharged from the second and third gas shower parts 22 and 23, that is, from a position away from the lower surface of the ceiling wall 10a, is dissociated with low energy. Therefore, it is possible to suppress generation of gas-phase reaction particles and clogging of the discharge hole 111 due to excessive dissociation of the SiH₄ gas which tends to be excessively dissociated.

Further, as in this example, by supplying only the SiH₄ gas from the second gas shower part 22 and not supplying the nitriding gas, the diffusion of the SiH₄ gas may be suppressed, and the generation of foreign matter containing Si may be suppressed.

When the formation of the SiN film is completed, the discharge of various gases into the chamber 2 and the emission of the microwave into the chamber 2 are stopped, and the wafer W is removed from the susceptor 11 and is unloaded from the chamber 2.

### Main Effects of the Present Embodiment

As described above, in the film forming apparatus 1 according to the present embodiment, the second gas shower part 22 includes the gas discharger 110 that discharges a gas toward the susceptor 11. Further, the gas discharger 110 (the second gas shower part 22 including the gas discharger 110) may adjust the gas discharge position in a predetermined plane and the distance from the center of the susceptor 11 to the gas discharge position may adjust the gas discharge position in the horizontal plane in the susceptor radial direction.

On the other hand, unlike the present embodiment, a film forming apparatus in the related art has a fixed discharge position in the horizontal plane in the second gas shower part 22 in the susceptor radial direction. For example, like the first gas shower part, a distance from the center of the susceptor 11 in a plan view is 80 mm.

In order to form a film uniformly in the wafer radial direction, it is necessary to make the plasma density of a gas on the surface of the wafer W placed on the susceptor 11 uniform in the wafer radial direction. When using the above-described film forming apparatus in the related art, as a method of realizing the uniformity of the plasma density in the wafer radial direction, for example, a method of adjusting at least one of the following (1) to (3) is conceivable.
(1) Film formation pressure
(2) In-plane balance of microwaves (specifically, balance between a microwave from the central dielectric window 63 and a microwave from the outer dielectric window 63)
(3) Balance between a flow rate of the material gas from the second gas shower part 22 and a flow rate of the material gas from the third gas shower part 23

However, the (1) above is determined according to a target film quality (specifically, a film stress, or the like) and may not change greatly. Therefore, when using the above-described film forming apparatus in the related art, the uniformity of the plasma density in the wafer radial direction may be achieved by adjusting at least one of the (2) and (3) above.

However, when using the above-described film forming apparatus in the related art, depending on the film formation pressure in the (1) above, with at least one of the (2) and (3) above, the plasma density on the surface of the wafer W may not be made uniform in the wafer radial direction, which makes it difficult to form a film uniformly in the wafer radial direction.

Specifically, when a SiN film is formed using the above-described film forming apparatus in the related art, the uniformity of film formation in the wafer radial direction by adjusting the (2) and (3) above may not be realized at a film formation pressure of 20 Pa even if it may be realized at a film formation pressure of 10 Pa.

FIGS. 11 and 12 are diagrams showing distributions of thickness and refractive index of a SiN film in the wafer radial direction, respectively. FIGS. 11 and 12 respectively show the results of film formation using the above-described film forming apparatus in the related art, with the film formation pressure set to 20 Pa and the (2) and (3) above adjusted to obtain substantially the best conditions. The horizontal axis in FIGS. 11 and 12 represents a distance from the center of the wafer W. The vertical axis of FIG. 11 represents the average value of the thicknesses (specifically, differences from the thickness at the center of the wafer W) in the wafer in-plane, and the vertical axis of FIG. 12 represents the average value of the refractive indexes (specifically, differences from the refractive index at the center of the wafer W) in the wafer in-plane.

Although not shown, when the SiN film is formed using the above-described film forming apparatus in the related art, the thickness and refractive index of the SiN film formed on the wafer W were uniform in the wafer radial direction when the film formation pressure is 10 Pa.

On the other hand, when the SiN film is formed using the above-described film forming apparatus in the related art with the film formation pressure of 20 Pa, as shown in FIG. 11, even if the (2) and (3) above are adjusted to obtain substantially the best conditions, the thickness of the SiN film formed on the wafer W was about 5% thinner than the wafer center at a position where a distance r from the wafer center is 100 mm. Further, as shown in FIG. 12, even if the (2) and (3) above are adjusted to obtain substantially the best conditions, the refractive index of the SiN film formed on the wafer W is about 0.025 smaller than the wafer center at a position where the distance r from the wafer center is 100 mm.

Further, although not shown, even if the (2) or (3) above is shifted from the conditions when the results of FIG. 11 are obtained, the film thickness difference and the refractive index difference between a position where the distance r from the wafer center is 50 mm and the position where the distance r is 100 mm were not improved.

In contrast, in the film forming apparatus 1 according to the present embodiment, as described above, the second gas shower part 22 may adjust the discharge position in the horizontal plane in the susceptor radial direction. Therefore, when the film forming apparatus 1 according to the present embodiment is used, there is the following (4) as a knob for improving the uniformity of the plasma density (specifically, the plasma density of the material gas) in the wafer radial direction on the surface of the wafer W, that is, a knob for improving the uniformity of film formation in the wafer diameter direction.
(4) Discharge position from the second gas shower part 22 in the horizontal plane in the susceptor radial direction

Therefore, even if the film formation pressure cannot sufficiently improve the uniformity of film formation in the wafer radial direction only by adjusting the (2) and (3) above, by also adjusting the (4) above, it is possible to improve the uniformity of film formation in the wafer radial direction.

In other words, according to the present embodiment, the uniformity of film formation in the wafer radial direction in the film forming apparatus 1 using the microwave may be improved without changing the film formation pressure.

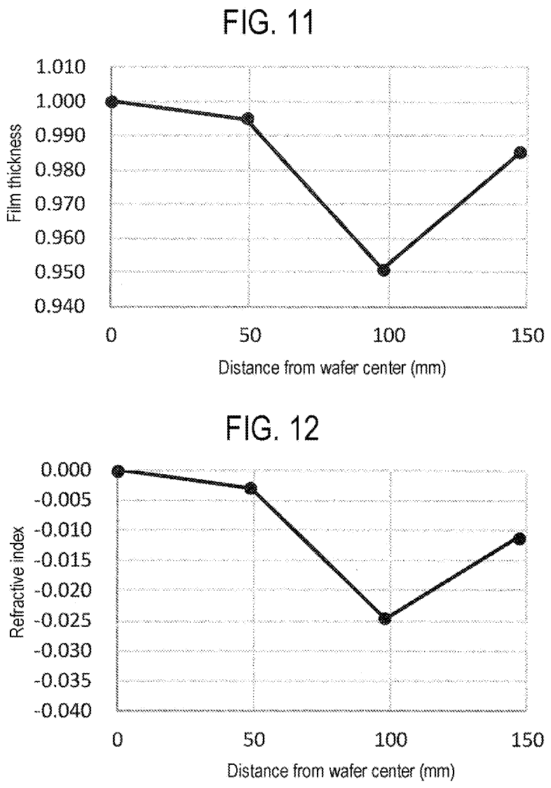

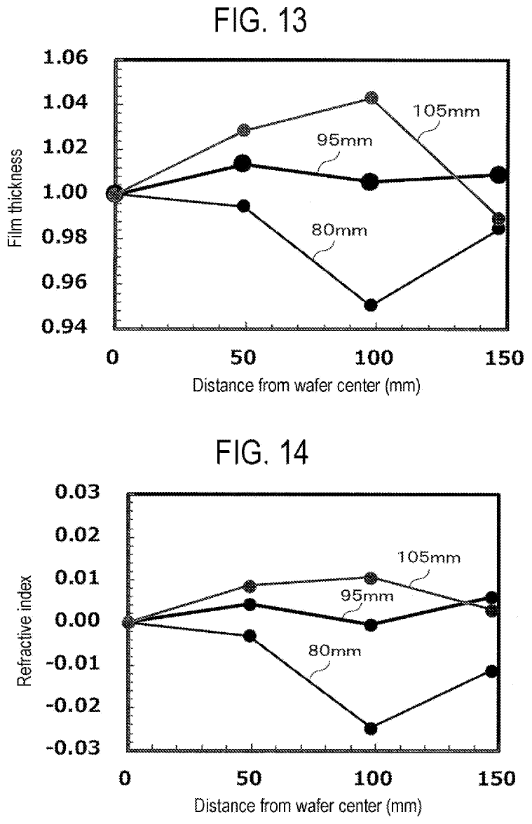

FIGS. 13 and 14 are diagrams showing the distributions of thickness and refractive index of a SiN film in the wafer radial direction, respectively. FIGS. 13 and 14 respectively show the results of film formation using the film forming apparatus 1, with the film formation pressure set to 20 Pa and the (2) and (3) above adjusted to obtain substantially the best conditions. The horizontal axis in FIGS. 13 and 14 represents a distance from the center of the wafer W. The vertical axis of FIG. 13 represents the average value of the thicknesses (specifically, thicknesses standardized on the base of the thickness at the center of the wafer W) in the wafer in-plane, and the vertical axis of FIG. 14 represents the average value of the refractive indexes (specifically, differences from the refractive index at the center of the wafer W) in the wafer in-plane.

When the flow path member 113D is used to set the discharge position from the second gas shower part 22 in the horizontal plane in the susceptor radial direction to 80 mm and set the film formation pressure to 20 Pa, as shown in FIG. 13, the thickness of the SiN film formed on the wafer W is about 5% thinner than the center of the wafer at a position where a distance r from the wafer center is 100 mm. Further, as shown in FIG. 14, the refractive index of the SiN film formed on the wafer W is about 0.025 smaller than the wafer center at a position where the distance r from the wafer center is 100 mm.

On the other hand, when the flow path member 113A is used to set the discharge position from the second gas shower part 22 in the horizontal plane in the susceptor radial direction to 105 mm and set the film formation pressure to 20 Pa, the thickness of the SiN film formed on the wafer W is about 4% thicker than the wafer center at the position where the distance r from the wafer center is 100 mm. Further, in the above case, the refractive index of the SiN film formed on the wafer W is slightly larger (specifically, about 0.011 larger) than the wafer center at the position where the distance r from the wafer center is 100 mm.

When the flow path member 113C is used to set the discharge position from the second gas shower part 22 in the horizontal plane in the susceptor radial direction to 95 mm and set the film formation pressure to 20 Pa, the thickness of the SiN film formed on the wafer W is about 0.6% thicker than the wafer center at the position where the distance r from the wafer center is 100 mm. Further, a film thickness difference from the wafer center is 1.4% or less even at the largest portion. Further, in the above case, the refractive index of the SiN film formed on the wafer W is substantially equal to that of the wafer center at the position where the distance r of from the wafer center is 100 mm. Further, a refractive index difference from the wafer center is 0.01 or less even at the largest portion.

Further, although not shown, a film stress of the SiN film formed at the film formation pressure of 20 Pa using the film forming apparatus 1 is a tensile stress regardless of the discharge position from the second gas shower part 22 in the horizontal plane in the susceptor radial direction.

From the test results shown in FIGS. 13 and 14, it may be seen that according to the present embodiment, the uniformity of film formation in the wafer radial direction may be improved without changing the film formation pressure.

When the SiN film is formed using the above-described film forming apparatus in the related art, the reason why the uniformity of the film formation results in the wafer radial direction differs between the film formation pressures of 10 Pa and 20 Pa, as described above, may be considered, for example, as follows.

That is, a film-forming gas supplied from a position at a distance r of 80 mm from the wafer center through the second gas shower part 22 moves inward in the wafer radial direction due to a gas flow from the third gas shower part 23, or moves outward in the wafer radial direction due to the influence of exhaust. When the film formation pressure is as low as 10 Pa and an exhaust speed is high, since the film-forming gas supplied from the position at the distance r of 80 mm from the wafer center through the second gas shower part 22 has the high exhaust speed as described above, a large proportion of the film-forming gas moves outward in the radial direction of the wafer W. In contrast, when the film formation pressure is as high as 20 Pa and an exhaust speed is low, a small proportion of the film-forming gas moves outward in the radial direction of the wafer W due to the exhaust. Therefore, when the film formation pressure is as high as 20 Pa, plasma of the film-forming gas may be insufficient at the position where the distance r from the wafer center is 100 mm, outside the position where the distance r from the wafer center is 80 mm. As a result, when the film formation pressure is 20 Pa, it is considered that the film formation results become non-uniform in the wafer radial direction.

In contrast, when the film forming apparatus 1 is used to set the film formation pressure to 20 Pa, by setting the discharge position from the second gas shower part 22 in the horizontal plane in the susceptor radial direction to 95 mm instead of 80 mm, it is possible to compensate for the lack of plasma of the film-forming gas at the position where the distance r from the wafer center is 100 mm. As a result, the uniformity of film formation in the wafer radial direction may be improved without changing the film formation pressure from 20 Pa.

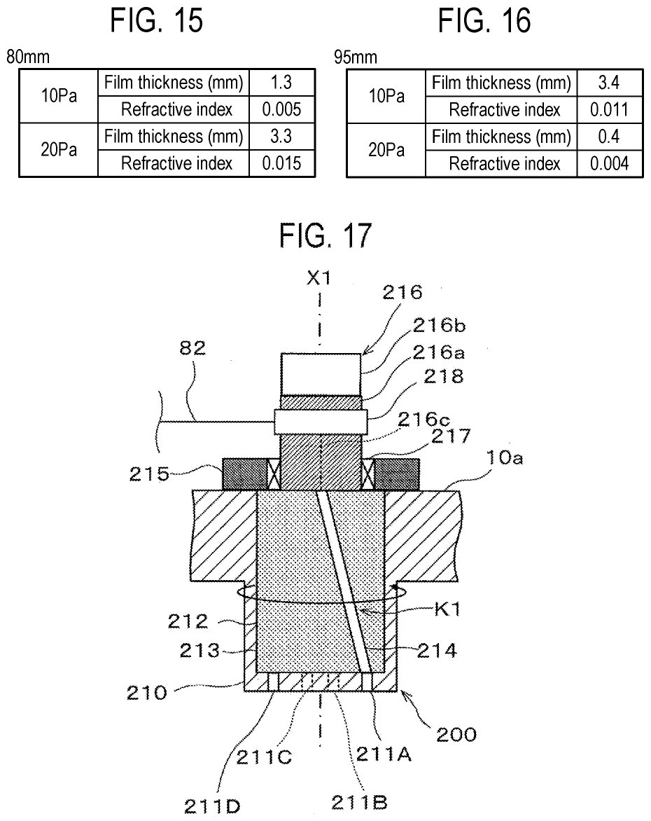

FIGS. 15 and 16 are tables showing a difference between the maximum and minimum values of the film thickness and refractive index in the wafer in-plane when the SiN film is formed by the film forming apparatus 1. In FIGS. 15 and 16, “film thickness” is a thickness standardized on the basis of the thickness at the center of the wafer W, and “refractive index” is a difference from the refractive index at the center of the wafer W. FIG. 15 shows the results when the flow path member 113d is used, that is, the results when the discharge position from the second gas shower part 22 in the horizontal plane in the susceptor radial direction is set to 80 mm. FIG. 16 shows the results when the flow path member 113C is used, that is, the results when the same discharge position is set to 95 mm. Further, during the film forming process, the balance of the above (3) is such that the flow rate of the material gas from the second gas shower part 22 is 25% of the total.

When the flow path member 113A is used to form the SiN film, that is, when the SiN film is formed with the discharge position from the second gas shower part 22 in the horizontal plane in the susceptor radial direction set to 80 mm, as shown in FIG. 15, a difference between the maximum and minimum values of the film thickness in the wafer in-plane is as small as 1.3% at the film formation pressure of 10 Pa. Further, a difference between the maximum and minimum values of the refractive index within the wafer surface is as small as 0.005.

On the other hand, a difference between the maximum and minimum values of the refractive index in the wafer in-plane is as small as 0.015 at the film formation pressure of 20 Pa, but a difference between the maximum and minimum values of the film thickness in the wafer in-plane is as large as 3.3%.

In contrast, when the flow path member 113C is used to form the SiN film, that is, when the SiN film is formed with the discharge position from the second gas shower part 22 in the horizontal plane in the susceptor radial direction set to 95 mm, as shown in FIG. 16, a difference between the maximum and minimum values of the refractive index in the wafer in-plane is as small as 0.011 at the film formation pressure of 10 Pa. However, a difference between the maximum and minimum values of the film thickness in the wafer in-plane is as large as 3.4%.

Further, a difference between the maximum and minimum values of the film thickness in the wafer in-plane is as small as 0.4% at the film formation pressure of 20 Pa, and a difference between the maximum and minimum values of the refractive index in the wafer in-plane is also as small as 0.004.

In other words, by changing the flow path member 113 used in the film forming apparatus 1 according to the film formation pressure, the SiN film may be uniformly formed in the wafer in-plane regardless of whether the film formation pressure is as small as 10 Pa or as large as 20 Pa.

### Second Embodiment

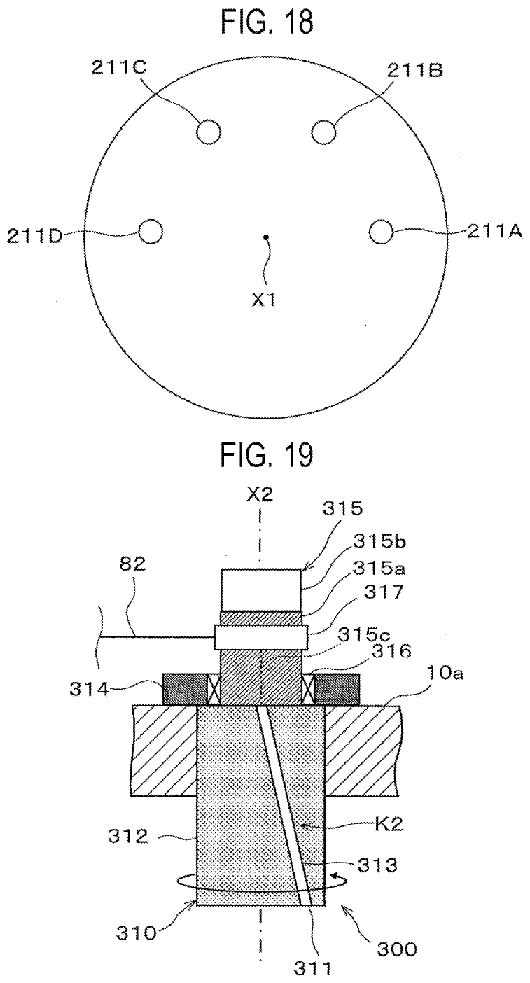

FIGS. 17 and 18 are a partially enlarged cross-sectional view and a bottom view, respectively, for explaining an outline of a gas discharger of a second gas shower part of a film forming apparatus as a plasma processing apparatus according to a second embodiment.

Similar to the second gas shower part 22 according to the first embodiment, a second gas shower part 200 shown in FIG. 17 also supplies a gas toward the susceptor 11 (specifically, downward) at a predetermined height between the ceiling wall 10a and the susceptor 11. The second gas shower part 200 also discharges the gas toward the susceptor 11, and a plurality of gas dischargers 210 are provided along the circumferential direction of the ceiling wall 10a in a plan view.

Similar to the gas discharger 110 according to the first embodiment, each gas discharger 210 includes therein a gas supply path K1 that guides a gas to a discharge position, that is, a discharge port, of the gas from the gas discharger 210. Further, each gas discharger 210 is also configured to be able to adjust the discharge position in the horizontal plane in the susceptor radial direction by changing the gas supply path K1.

Further, each gas discharger 210 is also configured to be able to selectively discharge a gas from a plurality of discharge positions (four discharge positions in this example) that are different from each other in the horizontal plane in the susceptor radial direction.

Each gas discharger 210 also includes discharge holes 211A to 211D. Hereinafter, the discharge holes 211A to 211D may be abbreviated as the discharge hole 211.

Similarly to the discharge hole 111 according to the first embodiment, the discharge hole 211 is also provided for each discharge position of the gas from the gas discharger 210 so as to correspond to the discharge position. However, unlike the discharge hole 111 according to the first embodiment, as shown in FIG. 18, the discharge position and the discharge hole 211 are arranged along the circumferential direction around a predetermined axis (specifically, the central axis X1 of the gas discharger 210) toward the susceptor 11.

Further, as shown in FIG. 17, each gas discharger 210 includes a recess 212 communicating with the discharge holes 211A to 211D. The recess 212 is formed, for example, so as to be cylindrically depressed downward from the upper surface of the ceiling wall 10a.

A flow path member 213 is arranged inside the recess 212. The flow path member 213 is configured to be able to change its direction around the predetermined axis within the recess 212. Specifically, the flow path member 213 is arranged inside the recess 212 so as to be rotatable around the central axis X1. The flow path member 213 forms a flow path 214 whose downstream end, that is, lower end, is selectively connected to one of the discharge holes 211. By rotating the flow path member 213 around the central axis X1 in the recess 212, that is, by changing the orientation of the flow path member 213, the discharge hole 211 to which the flow path 214 is connected may be selected.

Further, each gas discharger 210 includes a lid member 215 that closes an opening portion of the recess 212. A sealing member (not shown) such as an O-ring for sealing the chamber 2 is provided between the lid member 215 and the upper surface of the ceiling wall 10a.

Further, in each gas discharger 210, the upper end of the flow path member 213 is connected to a rotation mechanism 216. The rotation mechanism 216 includes a shaft 216a and a driving part 216b.

The shaft 216a extends vertically so as to pass through the lid member 215. A sealing member 217 is provided between the shaft 216a and the lid member 215. The sealing member 217 is a member that supports the shaft 216a and seals a space between the shaft 216a and the lid member 215, and is, for example, a magnetic fluid seal. The lower end of the shaft 216a is connected to the upper end of the flow path member 213, and the upper end of the shaft 216a is connected to the driving part 216b.

The driving part 216b includes, for example, a motor and generates a driving force for rotating the shaft 216a around the central axis X1. As the shaft 216a rotates around the central axis X1, the flow path member 213 rotates around the central axis X1 within the recess 212.

The shaft 216a may be formed integrally with the flow path member 213.

Further, the shaft 216a includes an introduction path 216c for introducing a gas into the flow path 214 of the flow path member 213. The introduction path 216c is connected to the upstream end, that is, the upper end, of the flow path 214 of the flow path member 213 arranged inside the recess 212. Further, the introduction path 216c is connected to one end of the above-described pipe 82 via a rotary joint 218. As described above, the other end of the pipe 82 is connected to the gas supplier 80 (see FIG. 1). Therefore, a gas from the gas supplier 80 is discharged from the discharge hole 211 corresponding to the orientation of the flow path member 213 toward the susceptor 11 (specifically, downward) through the pipe 82, the rotary joint 218, the introduction path 216c, and the flow path 214 of the flow path member 213 arranged inside the recess 112.

As described above, each gas discharger 210 is configured to be able to adjust the gas discharge position in the horizontal plane in the susceptor radial direction by changing the gas supply path K1. In the present embodiment, changing the gas supply path K1 means changing the orientation of the flow path member 213 in the recess 212, and each gas discharger 210 selectively discharges a gas from the discharge hole 211 corresponding to the orientation of the flow path member 213 in the recess 212.

Also in the film forming apparatus according to the present embodiment, the second gas shower part 200 includes the gas discharger 210. Then, the gas discharger 210 (the second gas shower part 200 having the gas discharger 210) may adjust the discharge position in the horizontal plane in the susceptor radial direction. Therefore, when the film forming apparatus according to the present embodiment is used, there is (4A) described below, in addition to the (2) and (3) above, as a knob for improving the uniformity of the plasma density (specifically, the plasma density of the material gas) in the wafer radial direction on the surface of the wafer W, that is, a knob for improving the uniformity of film formation in the wafer diameter direction.
(4A) Discharge position from the second gas shower part 200 in the horizontal plane in the susceptor radial direction

Therefore, even if the film formation pressure cannot sufficiently improve the uniformity of film formation in the wafer radial direction only by adjusting the above (2) and (3), by also adjusting (4A) above, it is possible to improve the uniformity of film formation in the wafer radial direction.

In other words, according to the present embodiment as well, the uniformity of film formation in the wafer radial direction in the film forming apparatus using a microwave may be improved regardless of the film formation pressure.

### Third Embodiment

FIG. 19 is a partially enlarged cross-sectional view for explaining the outline of a gas discharger of a second gas shower part of a film forming apparatus as a plasma processing apparatus according to a third embodiment.

Similar to the second gas shower part 22 according to the first embodiment, a second gas shower part 300 shown in FIG. 19 also supplies a gas toward the susceptor 11 (specifically, downward) at a predetermined height between the ceiling wall 10a and the susceptor 11. The second gas shower part 300 also includes a that discharges the gas toward the susceptor 11, and a plurality of gas dischargers 310 are provided along the circumferential direction of the ceiling wall 10a in a plan view.

Similar to the gas discharger 110 according to the first embodiment, each gas discharger 310 includes therein a gas supply path K2 that guides a gas to a discharge position, that is, a gas discharge port 311, of the gas from the gas discharger 310. Further, each gas discharger 310 is also configured to be able to adjust the discharge position in the horizontal plane in the susceptor radial direction by changing the gas supply path K2.

However, unlike the gas discharger 110 according to the first embodiment, each gas discharger 310 includes one gas discharge port 311 provided at a position spaced apart from a predetermined axis (specifically, the central axis X2 of the gas discharger 310) toward the susceptor 11.

Each gas discharger 310 also includes a flow path member 312. The flow path member 312 forms a flow path 313 that communicates with the gas discharge port 311.

The flow path member 312 is configured to be able to change its direction around the predetermined axis. Specifically, the flow path member 312 is attached so as to be rotatable around the central axis X2 and to penetrate through the ceiling wall 10a. By rotating the flow path member 312 around the central axis X2, that is, by changing the orientation of the flow path member 312, the gas discharge position in the horizontal plane in the susceptor radial direction may be adjusted.

Further, each gas discharger 310 includes a lid member 314 that closes a portion of the ceiling wall 10a through which the flow path member 312 penetrates. A sealing member (not shown) such as an O-ring for sealing the chamber 2 is provided between the lid member 314 and the upper surface of the ceiling wall 10a.

Further, in each gas discharger 310, the upper end of the flow path member 312 is connected to a rotation mechanism 315. The rotation mechanism 315 includes a shaft 315a and a driving part 315b.

The shaft 315a extends vertically so as to pass through the lid member 314. A sealing member 316 is provided between the shaft 315a and the lid member 314. The sealing member 316 is a member that supports the shaft 315a and seals a space between the shaft 315a and the lid member 314, and is, for example, a magnetic fluid seal. The lower end of the shaft 315a is connected to the upper end of the flow path member 312, and the upper end of the shaft 315a is connected to the driving part 315b.

The driving part 315b includes, for example, a motor and generates a driving force for rotating the shaft 315a around the central axis X2. As the shaft 315a rotates around the central axis X2, the flow path member 312 rotates around the central axis X2.

The shaft 315a may be formed integrally with the flow path member 312.

Further, the shaft 315a includes an introduction path 315c for introducing a gas into the flow path 313 of the flow path member 312. The introduction path 315c is connected to the upstream end, that is, the upper end, of the flow path 313 of the flow path member 312. Further, the introduction path 315c is connected to one end of the above-described pipe 82 via a rotary joint 317. As described above, the other end of the pipe 82 is connected to the gas supplier 80 (see FIG. 1). Therefore, a gas from the gas supplier 80 is discharged from the gas discharge port 311 corresponding to the orientation of the flow path member 312 toward the susceptor 11 (specifically, downward) through the pipe 82, the rotary joint 317, the introduction path 315c, and the flow path 313 of the flow path member 312.

As described above, each gas discharger 310 is configured to be able to adjust the gas discharge position in the horizontal plane in the susceptor radial direction by changing the gas supply path K2. In the present embodiment, changing the gas supply path K2 means changing the orientation of the flow path member 312, and each gas discharger 310 discharges a gas from the gas discharge port 311 located at a position corresponding to the orientation of the flow path member 312.

Further, a cover member (not shown) may be provided to cover a portion of the flow path member 312 located inside the chamber 2. The cover member may be formed integrally with the ceiling wall 10a of the chamber 2.

Also in the film forming apparatus according to the present embodiment, the second gas shower part 300 includes the gas discharger 310. Then, the gas discharger 310 (the second gas shower part 300 having the gas discharger 310) may adjust the discharge position in the horizontal plane in the susceptor radial direction. Therefore, when the film forming apparatus according to the present embodiment is used, there (4B) described below, in addition to the (2) and (3) above, as a knob for improving the uniformity of the plasma density (specifically, the plasma density of the material gas) in the wafer radial direction on the surface of the wafer W, that is, a knob for improving the uniformity of film formation in the wafer diameter direction.
(4B) Discharge position from the second gas shower part 300 in the horizontal plane in the susceptor radial direction

Therefore, even if the film formation pressure cannot sufficiently improve the uniformity of film formation in the wafer radial direction only by adjusting the (2) and (3) above, by also adjusting (4B) above, it is possible to improve the uniformity of film formation in the wafer radial direction.

In other words, according to the present embodiment as well, the uniformity of film formation in the wafer radial direction in the film forming apparatus using a microwave may be improved regardless of the film formation pressure.

### Fourth Embodiment

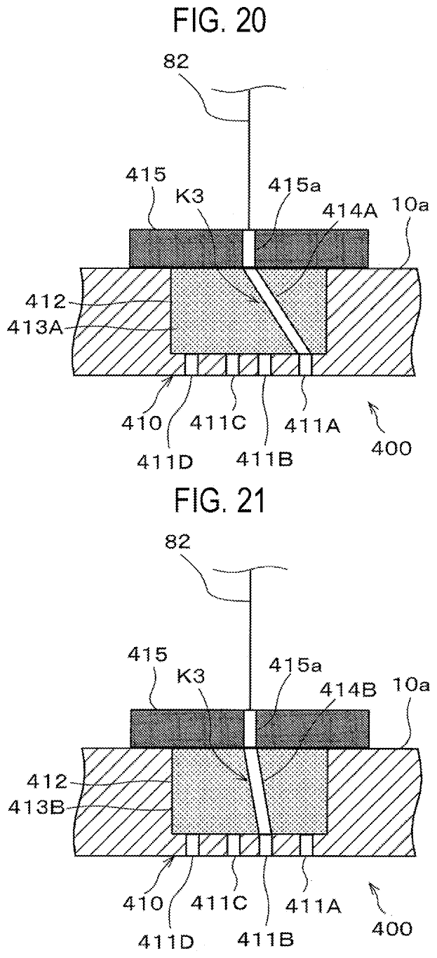

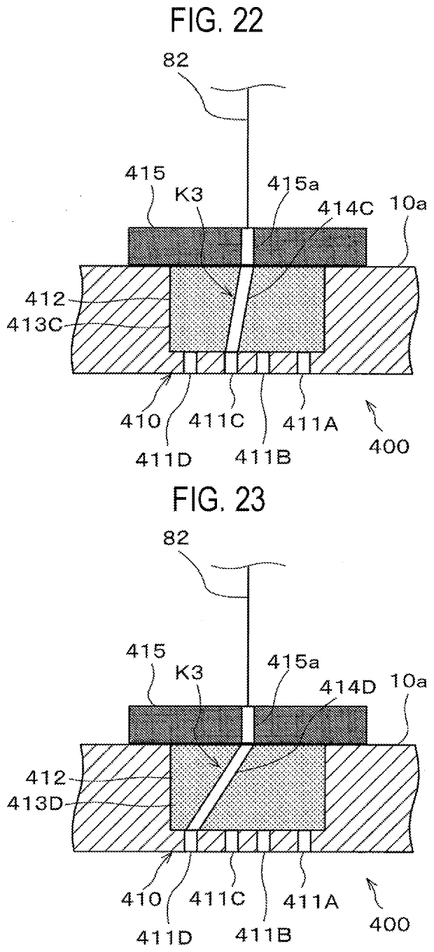

FIGS. 20 to 23 are partially enlarged cross-sectional views for explaining the outline of a gas discharger of a first gas shower part of a film forming apparatus as a plasma processing apparatus according to a fourth embodiment.

As shown in FIG. 20, similarly to the first to third embodiments, the film forming apparatus according to the present embodiment also includes a gas discharger 410 configured to be able to adjust a gas discharge position within a predetermined plane. The gas discharger 410 discharges a gas toward the susceptor 11. The gas discharger 410 is configured to be able to adjust the gas discharge position in the predetermined plane and a distance from the center of the susceptor 11 to the gas discharge position by changing a gas supply path K3 existing in the gas discharger 410.

In the first to third embodiments, the gas dischargers 110, 210, and 310 are included in the second gas shower parts 22, 200, and 300, respectively, which supply a gas at a predetermined height between the ceiling wall 10a of the chamber 2 and the susceptor 11. In contrast, in the present embodiment, the gas discharger 410 is included in a first gas shower part 400 that supplies a gas from the ceiling wall 10a.

A plurality of gas dischargers 410 are provided along the circumferential direction of the ceiling wall 10a (that is, the circumferential direction of the susceptor 11) in a plan view. More specifically, a plurality of gas dischargers 410 (for example, eight gas dischargers 410) are arranged at equal intervals on the same circumference around the center of the ceiling wall 10a (that is, the center of the susceptor 11) in a plan view.

As described above, each gas discharger 410 is configured to be able to adjust the gas discharge position in the predetermined plane and the distance from the center of the susceptor 11 to the discharge position by changing the gas supply path K3. Specifically, each gas discharger 410 is configured to be able to adjust the discharge position in the horizontal plane in the susceptor radial direction by changing the gas supply path K3.

Further, each gas discharger 410 is configured to selectively discharge a gas from a plurality of discharge positions having different distances from the center of the susceptor 11. Specifically, each gas discharger 410 is configured to be able to selectively discharge the gas from a plurality of discharge positions (four discharge positions in this example) that are different from each other in the horizontal plane in the susceptor radial direction.

In the present embodiment, each gas discharger 410 includes discharge holes 411A to 411D. Hereinafter, the discharge holes 411A to 411D may be abbreviated as the discharge hole 411.

The discharge hole 411 is provided for each discharge position of the gas from the gas discharger 410 so as to correspond to the discharge position. The discharge holes 411 are arranged, for example, in the horizontal plane in the susceptor radial direction. Further, the discharge hole 411 is formed at the lower end of the ceiling wall 10a.

Further, each gas discharger 410 includes a recess 412 communicating with each of the discharge holes 411A to 411D. The recess 412 is formed, for example, so as to be cylindrically depressed downward from the upper surface of the ceiling wall 10a.

As shown in FIGS. 20 to 23, any one of flow path members 413A to 413D may be inserted into and removed from the recess 412. Hereinafter, the flow path members 413A to 413D may be abbreviated as the flow path member 413, and flow paths 414A to 414D, which will be described later, may be abbreviated as a flow path 414.

The flow path member 413A forms the flow path 414A whose downstream end, that is, lower end, is connected only to the discharge hole 411A.

The flow path member 413B forms the flow path 414B whose downstream end, that is, lower end, is connected only to the discharge hole 411B.

The flow path member 413C forms the flow path 414C whose downstream end, that is, lower end, is connected only to the discharge hole 411C.

The flow path member 413D forms the flow path 414D whose downstream end, that is, lower end, is connected only to the discharge hole 411D.

That is, the gas discharger 410 includes a flow path member 413 that forms the flow path 414 arranged inside the recess 412 and connected to one of the discharge hole 411. Then, the flow path members 413A to 413D are selectively used.

Further, each gas discharger 410 includes a lid member 415 that closes an opening portion of the recess 412.

The lid member 415 includes an introduction hole 415a for introducing a gas into the flow path 414 of the flow path member 413. The introduction hole 415a communicates with the interior of the recess 412 when the lid member 415 is attached to the ceiling wall 10a, and is connected to the upstream end, that is, the upper end, of the flow path 414 of the flow path member 413 arranged within the recess 412. In the present embodiment, the introduction hole 415a is connected to one end of the pipe 82. The other end of the pipe 82 is connected to the gas supplier 80 (see FIG. 1). Therefore, a gas from the gas supplier 80 is discharged from the discharge hole 411 corresponding to one of the flow path members 413 arranged inside the recess 412 toward the susceptor 11 (specifically, downward) through the pipe 82, the introduction hole 415a, and the flow path 414 of the flow path member 413.

As described above, each gas discharger 410 is configured to be able to adjust the gas discharge position in the horizontal plane in the susceptor radial direction by changing the gas supply path K3. In the present embodiment, changing the gas supply path K3 means changing the flow path member 413 arranged inside the recess 412, and each gas discharger 410 selectively discharges a gas from the discharge hole 411 corresponding to the flow path member 413 arranged inside the recess 412. For example, when the flow path member 413A is used, each gas discharger 410 selectively discharges the gas from the discharge hole 411A corresponding to the flow path member 413A.

In the case of the present embodiment, the second gas shower part that supplies a gas at a predetermined height between the ceiling wall 10a and the susceptor 11 may have the same configuration as in the first to third embodiments, or may have the same configuration as that in the related art. The same applies to fifth and sixth embodiments, which will be described later.

In the film forming apparatus according to the present embodiment, by changing the flow path member 413 used in the gas discharger 410 of the first gas shower part 400, it is possible to adjust the discharge position of the gas from the first gas shower part 400 in the horizontal plane in the susceptor radial direction. As a result, it is possible to adjust the distribution of plasma density on the surface of the wafer W in the wafer radial direction. Therefore, according to the present embodiment as well, it is possible to improve the uniformity of film formation in the wafer radial direction in the film formation apparatus using a microwave regardless of the film formation pressure.

### Fifth Embodiment

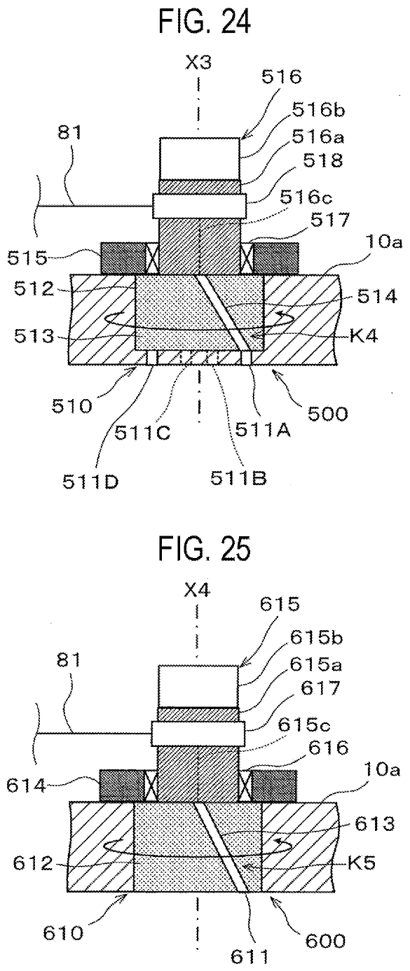

FIG. 24 is a partially enlarged cross-sectional view for explaining the outline of a gas discharger of a first gas shower part of a film forming apparatus as a plasma processing apparatus according to a fifth embodiment.

Similarly to the first gas shower part 400 according to the fourth embodiment, a first gas shower part 500 shown in FIG. 24 also supplies a gas from the ceiling wall 10a. The first gas shower part 500 also includes a gas discharger 510 that discharges a gas toward the susceptor 11, and a plurality of gas dischargers 510 are provided along the circumferential direction of the ceiling wall 10a in a plan view.

Similarly to the gas discharger 410 according to the fourth embodiment, each gas discharger 510 includes therein a gas supply path K4 that guides a gas to a discharge position, that is, a discharge port, of the gas from the gas discharger 510. Further, each gas discharger 510 is also configured to be able to adjust the discharge position in the horizontal plane in the susceptor radial direction by changing the gas supply path K4.

Further, each gas discharger 510 is also configured to be able to selectively discharge a gas from a plurality of discharge positions (four discharge positions in this example) that are different from each other in the horizontal plane in the susceptor radial direction.

Each gas discharger 510 also includes discharge holes 511A to 511D. Hereinafter, the discharge holes 511A to 511D may be abbreviated as the discharge hole 511.

Similarly to the discharge hole 411 according to the fourth embodiment, the discharge hole 511 is also provided for each discharge position of the gas from the gas discharger 510 so as to correspond to the discharge position. The discharge hole 511 is also formed at the lower end of the ceiling wall 10a. However, unlike the discharge hole 411 according to the fourth embodiment, the discharge position and the discharge hole 511 are arranged in the circumferential direction around a predetermined axis (specifically, the central axis X3 of the gas discharger 510) toward the susceptor 11.

Further, each gas discharger 510 includes a recess 512 communicating with each of the discharge holes 511A to 511D. The recess 512 is formed, for example, so as to be cylindrically depressed downward from the upper surface of the ceiling wall 10a.

A flow path member 513 is arranged inside the recess 512. The flow path member 513 is configured to be able to change its direction around the predetermined axis within the recess 512. Specifically, the flow path member 513 is arranged inside the recess 512 so as to be rotatable around the central axis X3. The flow path member 513 forms a flow path 514 whose downstream end, that is, lower end, is selectively connected to one of the discharge holes 511. By rotating the flow path member 513 around the central axis X3 in the recess 512, that is, by changing the orientation of the flow path member 513, the discharge hole 511 to which the flow path 514 is connected may be selected.

Further, each gas discharger 510 includes a lid member 515 that closes an opening portion of the recess 512. A sealing member (not shown) such as an O-ring for sealing the chamber 2 is provided between the lid member 515 and the upper surface of the ceiling wall 10a.

Further, in each gas discharger 510, the upper end of the flow path member 513 is connected to a rotation mechanism 516. The rotation mechanism 516 includes a shaft 516a and a driving part 516b.

The shaft 516a extends vertically so as to pass through the lid member 515. A sealing member 517 is provided between the shaft 516a and the lid member 515. The sealing member 517 is a member that supports the shaft 516a and seals a space between the shaft 516a and the lid member 515, and is, for example, a magnetic fluid seal. The lower end of the shaft 516a is connected to the upper end of the flow path member 513, and the upper end of the shaft 516a is connected to the driving part 516b.

The driving part 516b includes, for example, a motor and generates a driving force for rotating the shaft 516a around the central axis X3. As the shaft 516a rotates around the central axis X3, the flow path member 513 rotates around the central axis X3 within the recess 512.

The shaft 516a may be formed integrally with the flow path member 513.

Further, the shaft 516a includes an introduction path 516c for introducing a gas into the flow path 514 of the flow path member 513. The introduction path 516c is connected to the upstream end, that is, the upper end, of the flow path 514 of the flow path member 513 arranged inside the recess 512. Further, the introduction path 516c is connected to one end of the pipe 81 via a rotary joint 518. The other end of the pipe 81 is connected to the gas supplier 80 (see FIG. 1). Therefore, a gas from the gas supplier 80 is discharged from the discharge hole 511 corresponding to the orientation of the flow path member 513 toward the susceptor 11 (specifically, downward) through the pipe 81, the rotary joint 518, the introduction path 516c, and the flow path 514 of the flow path member 513 arranged inside the recess 512.

As described above, each gas discharger 510 is configured to be able to adjust the gas discharge position in the horizontal plane in the susceptor radial direction by changing the gas supply path K4. In the present embodiment, changing the gas supply path K4 means changing the orientation of the flow path member 513 in the recess 512, and each gas discharger 510 selectively discharges a gas from the discharge hole 511 corresponding to the orientation of the flow path member 513 in the recess 512.

In the film forming apparatus according to the present embodiment, by changing the orientation of the flow path member 513 in the recess 512, it is possible to adjust the discharge position of the gas from the first gas shower part 500 in the horizontal plane in the susceptor radial direction. As a result, it is possible to adjust the distribution of plasma density on the surface of the wafer W in the wafer radial direction. Therefore, according to the present embodiment as well, it is possible to improve the uniformity of film formation in the wafer radial direction in the film formation apparatus using a microwave regardless of the film formation pressure.

### Sixth Embodiment

FIG. 25 is a partially enlarged cross-sectional view for explaining an outline of a gas discharger of a first gas shower part of a film forming apparatus as a plasma processing apparatus according to a sixth embodiment.

Similarly to the first gas shower part 400 according to the fourth embodiment, a first gas shower part 600 shown in FIG. 25 also supplies a gas from the ceiling wall 10a. The first gas shower part 600 also includes a gas discharger 610 that discharges a gas toward the susceptor 11, and a plurality of gas dischargers 610 are provided along the circumferential direction of the ceiling wall 10a in a plan view.

Similarly to the gas discharger 410 according to the fourth embodiment, each gas discharger 610 includes therein a gas supply path K5 that guides a gas to a discharge position, that is, a gas discharge port 611, of the gas from the gas discharger 610. Further, each gas discharger 610 is also configured to be able to adjust the discharge position in the horizontal plane in the susceptor radial direction by changing the gas supply path K5.

However, unlike the gas discharger 410 according to the fourth embodiment, each gas discharger 610 includes one gas discharge port 611 provided at a position spaced apart from a predetermined axis (specifically, the central axis X4 of the gas discharger 610) toward the susceptor 11.

Each gas discharger 610 also includes a flow path member 612. The flow path member 612 forms a flow path 613 that communicates with the gas discharge port 611.

The flow path member 612 is configured to be able to change its direction around the predetermined axis. Specifically, the flow path member 612 is attached so as to be rotatable around the central axis X4 and to penetrate through the ceiling wall 10a. By rotating the flow path member 612 around the central axis X4, that is, by changing the orientation of the flow path member 612, the gas discharge position in the horizontal plane in the susceptor radial direction may be adjusted.

Further, each gas discharger 610 includes a lid member 614 that closes a portion of the ceiling wall 10a through which the flow path member 612 penetrates. A sealing member (not shown) such as an O-ring for sealing the chamber 2 is provided between the lid member 614 and the upper surface of the ceiling wall 10a.

Further, in each gas discharger 610, the upper end of the flow path member 612 is connected to a rotation mechanism 615. The rotation mechanism 615 includes a shaft 615a and a driving part 615b.

The shaft 615a extends vertically so as to pass through the lid member 614. A sealing member 616 is provided between the shaft 615a and the lid member 614. The sealing member 616 is a member that supports the shaft 615a and seals a space between the shaft 615a and the lid member 614, and is, for example, a magnetic fluid seal. The lower end of the shaft 615a is connected to the upper end of the flow path member 612, and the upper end of the shaft 615a is connected to the driving part 615b.

The driving part 615b includes, for example, a motor and generates a driving force for rotating the shaft 615a around the central axis X4. As the shaft 615a rotates around the central axis X4, the flow path member 612 rotates around the central axis X4.

The shaft 615a may be formed integrally with the flow path member 612.

Further, the shaft 615a includes an introduction path 615c for introducing a gas into the flow path 613 of the flow path member 612. The introduction path 615c is connected to the upstream end, that is, the upper end, of the flow path 613 of the flow path member 612. Further, the introduction path 615c is connected to one end of the pipe 81 via a rotary joint 617. The other end of the pipe 81 is connected to the gas supplier 80 (see FIG. 1). Therefore, a gas from the gas supplier 80 is discharged from the gas discharge port 611 at a position corresponding to the orientation of the flow path member 612 toward the susceptor 11 (specifically, downward) through the pipe 81, the rotary joint 617, the introduction path 615c, and the flow path 613 of the flow path member 612.

As described above, each gas discharger 610 is configured to be able to adjust the gas discharge position, that is, the position of the gas discharge port 611, in the horizontal plane in the susceptor radial direction by changing the gas supply path K5. In the present embodiment, changing the gas supply path K5 means changing the orientation of the flow path member 612, and each gas discharger 610 discharges a gas from the gas discharge port 611 located at a position corresponding to the orientation of the flow path member 612.

Further, a cover member (not shown) may be provided to cover a portion of the flow path member 612 exposed inside the chamber 2. The cover member may be formed integrally with the ceiling wall 10a of the chamber 2.

In the film forming apparatus according to the present embodiment, by changing the orientation of the flow path member 612, it is possible to adjust the discharge position of the gas from the first gas shower part 600 in the horizontal plane in the susceptor radial direction. As a result, it is possible to adjust the distribution of plasma density on the surface of the wafer W in the wafer radial direction. Therefore, according to the present embodiment as well, it is possible to improve the uniformity of film formation in the wafer radial direction in the film formation apparatus using a microwave regardless of the film formation pressure.

### Seventh Embodiment

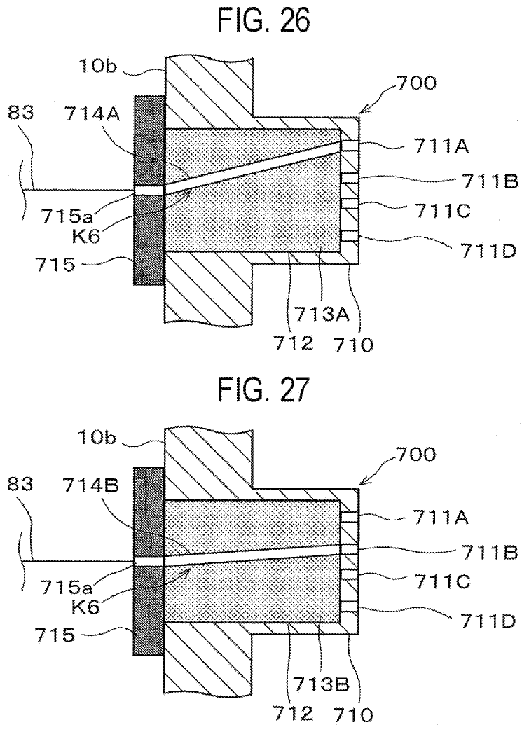

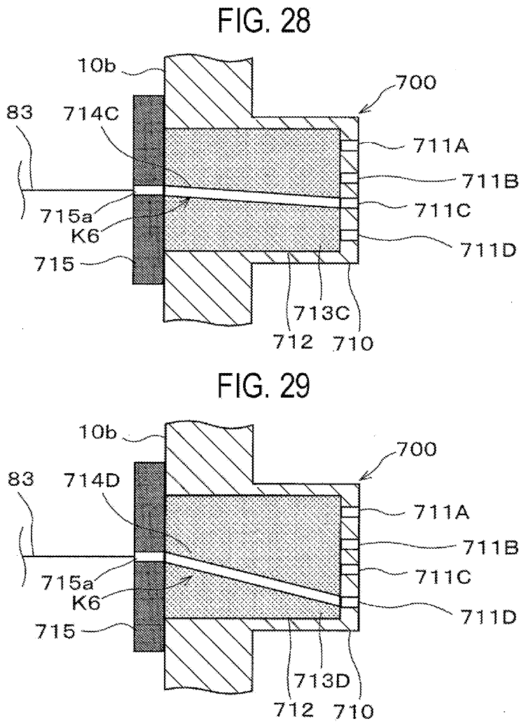

FIGS. 26 to 29 are partially enlarged cross-sectional views for explaining an outline of a gas discharger of a third gas shower part of a film forming apparatus as a plasma processing apparatus according to a seventh embodiment.

As shown in FIG. 26, similarly to the first to third embodiments, the film forming apparatus according to the present embodiment also includes a gas discharger 710 configured to be able to adjust a gas discharge position within a predetermined plane. The gas discharger 710 discharges a gas toward the susceptor 11. The gas discharger 710 is configured to be able to adjust the gas discharge position in the predetermined plane and a distance from the center of the susceptor 11 to the gas discharge position by changing a gas supply path K6 existing in the gas discharger 710.

In the first to third embodiments, the gas dischargers 110, 210, and 310 are included in the second gas shower parts 22, 200, and 300, respectively, which supply a gas at a predetermined height between the ceiling wall 10a of the chamber 2 and the susceptor 11. In contrast, in the present embodiment, the gas discharger 710 is included in a third gas shower part 700 that supplies a gas from the side of the susceptor 11.

A plurality of gas dischargers 710 are provided along the circumferential direction of the ceiling wall 10a (that is, the circumferential direction of the susceptor 11) in a plan view. More specifically, a plurality of gas dischargers 710 (for example, 20 gas dischargers 710) are arranged at equal intervals on the same circumference around the center of the ceiling wall 10a (that is, the center of the susceptor 11) in a plan view.

As described above, each gas discharger 710 is configured to be able to adjust the gas discharge position in the predetermined plane and the distance from the center of the susceptor 11 to the discharge position by changing the gas supply path K6. Specifically, each gas discharger 710 is configured to be able to adjust the discharge position in the vertical plane in the vertical direction by changing the gas supply path K6.

Further, each gas discharger 710 is configured to selectively discharge a gas from a plurality of discharge positions having different distances from the center of the susceptor 11. Specifically, each gas discharger 710 is configured to be able to selectively discharge the gas from a plurality of discharge positions (four discharge positions in this example) that are different from each other in the vertical plane in the vertical direction.

In the present embodiment, each gas discharger 710 includes discharge holes 711A to 711D. Hereinafter, the discharge holes 711A to 711D may be abbreviated as the discharge hole 711.

The discharge hole 711 is provided for each discharge position of the gas from the gas discharger 710 so as to correspond to the discharge position. The discharge holes 711 are vertically arranged, for example, in the vertical plane.

The gas discharger 710 is formed such that its leading end side portion extends horizontally from the sidewall 10b toward the center of the chamber 2 in a plan view, and the discharge hole 711 is formed at the leading end of the gas discharger 710.

Further, each gas discharger 710 includes a recess 712 communicating with each of the discharge holes 711A to 711D. The recess 712 is formed, for example, so as to be depressed cylindrically inward from the outer surface of the sidewall 10b.

As shown in FIGS. 26 to 29, any one of flow path members 713A to 713D may be inserted into and removed from the recess 712. Hereinafter, the flow path members 713A to 713D may be abbreviated as the flow path member 713, and flow paths 714A to 714D, which will be described later, may be abbreviated as a flow path 714.

The flow path member 713A forms the flow path 714A whose downstream end, that is, leading end, is connected only to the discharge hole 711A.

The flow path member 713B forms the flow path 714B whose downstream end, that is, leading end, is connected only to the discharge hole 711B.

The flow path member 713C forms the flow path 714C whose downstream end, that is, leading end, is connected only to the discharge hole 711C.

The flow path member 713D forms the flow path 714D whose downstream end, that is, leading end, is connected only to the discharge hole 711D.

That is, the gas discharger 710 includes a flow path member 713 that forms the flow path 714 arranged inside the recess 712 and connected to one of the discharge hole 711. Then, the flow path members 713A to 713D are selectively used.

Further, each gas discharger 410 includes a lid member 715 that closes an opening portion of the recess 712.

The lid member 715 includes an introduction hole 715a for introducing a gas into the flow path 714 of the flow path member 713. The introduction hole 715a communicates with the interior of the recess 712 when the lid member 715 is attached to the sidewall 10b, and is connected to the upstream end, that is, the base end, of the flow path 714 of the flow path member 713 arranged within the recess 712. In the present embodiment, the introduction hole 715a is connected to one end of the pipe 83. The other end of the pipe 83 is connected to the gas supplier 80 (see FIG. 1). Therefore, a gas from the gas supplier 80 is discharged from the discharge hole 711 corresponding to one of the flow path members 713 arranged inside the recess 712 toward the susceptor 11 (specifically, horizontally) through the pipe 83, the introduction hole 715a, and the flow path 714 of the flow path member 713.

As described above, each gas discharger 710 is configured to be able to adjust the gas discharge position in the vertical plane in the vertical direction by changing the gas supply path K6. In the present embodiment, changing the gas supply path K6 means changing the flow path member 713 arranged inside the recess 712, and each gas discharger 710 selectively discharges a gas from the discharge hole 711 corresponding to the flow path member 713 arranged inside the recess 712. For example, when the flow path member 713A is used, each gas discharger 710 selectively discharges the gas from the discharge hole 711A corresponding to the flow path member 713A.

In the case of the present embodiment, the second gas shower part that supplies a gas at a predetermined height between the ceiling wall 10a and the susceptor 11 may have the same configuration as in the first to third embodiments, or may have the same configuration as that in the related art. Further, the first gas shower part that supplies a gas from the ceiling wall 10a may have the same configuration as in the fourth to sixth embodiments, or may have the same configuration as that in the related art. This holds true with respect to the eighth and ninth embodiments, which will be described later.

In the film forming apparatus according to the present embodiment, by changing the flow path member 713 used in the gas discharger 710 of the third gas shower part 700, it is possible to adjust the discharge position of the gas from the third gas shower part 700 in the vertical plane in the vertical direction. As a result, it is possible to adjust the distribution of plasma density on the surface of the wafer W in the wafer radial direction. For example, it is possible to increase the plasma density of the material gas at the center of the wafer W on the susceptor 11 by shifting (that is, raising) the discharge position of the gas from the third gas shower part 700 in the positive vertical direction. Therefore, according to the present embodiment as well, it is possible to improve the uniformity of film formation in the wafer radial direction in the film formation apparatus using a microwave regardless of the film formation pressure.

### Eighth Embodiment

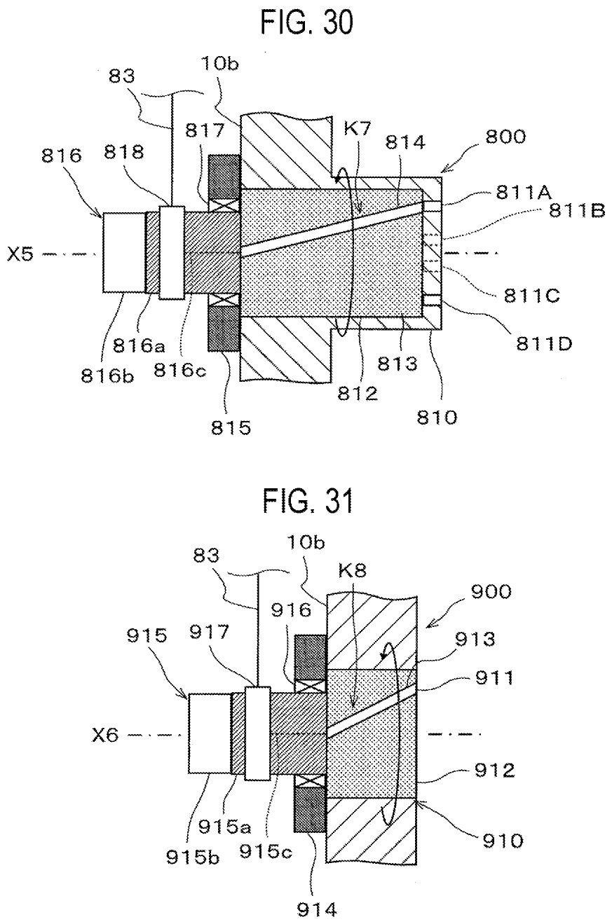

FIG. 30 is a partially enlarged cross-sectional view for explaining the outline of a gas discharger of a third gas shower part of a film forming apparatus as a plasma processing apparatus according to an eighth embodiment.

A third gas shower part 800 shown in FIG. 30 also supplies a gas from the side of the susceptor 11. The third gas shower part 800 also includes a gas discharger 810 that discharges the gas toward the susceptor 11, and a plurality of gas dischargers 810 are provided along the circumferential direction of the ceiling wall 10a in a plan view.

Similarly to the gas discharger 710 according to the seventh embodiment, each gas discharger 810 includes therein a gas supply path K7 that guides a gas to a discharge position, that is, a discharge port, of the gas from the gas discharger 810. Further, each gas discharger 810 is also configured to be able to adjust the discharge position in the vertical plane in the vertical direction by changing the gas supply path K7.

Further, each gas discharger 810 is also configured to be able to selectively discharge a gas from a plurality of discharge positions (four discharge positions in this example) that are different from each other in the vertical plane in the vertical direction.

Each gas discharger 810 also includes discharge holes 811A to 811D. Hereinafter, the discharge holes 811A to 811D may be abbreviated as the discharge hole 811.

Similarly to the discharge hole 711 according to the seventh embodiment, the discharge hole 811 is also provided for each discharge position of the gas from the gas discharger 810 so as to correspond to the discharge position. However, unlike the discharge hole 711 according to the seventh embodiment, the discharge position and the discharge hole 811 are arranged in the circumferential direction around a predetermined axis (specifically, the central axis X5 of the gas discharger 810) toward the susceptor 11.

Further, each gas discharger 810 includes a recess 812 communicating with each of the discharge holes 811A to 811D. The recess 812 is formed, for example, so as to be depressed cylindrically inward from the outer surface of the sidewall 10b.

A flow path member 813 is arranged inside the recess 812. The flow path member 813 is configured to be able to change its direction about the predetermined axis within the recess 812. Specifically, the flow path member 813 is arranged inside the recess 812 so as to be rotatable around the central axis X5. The flow path member 813 forms a flow path 814 whose downstream end, that is, leading end, is selectively connected to one of the discharge holes 811. By rotating the flow path member 813 around the central axis X5 in the recess 812, that is, by changing the orientation of the flow path member 813, the discharge hole 811 to which the flow path 814 is connected may be selected.

Further, each gas discharger 810 includes a lid member 815 that closes an opening portion of the recess 812. A sealing member (not shown) such as an O-ring for sealing the chamber 2 is provided between the lid member 815 and the outer surface of the sidewall 10b.

Further, in each gas discharger 810, the base end of the flow path member 813 is connected to a rotation mechanism 816. The rotation mechanism 816 includes a shaft 816a and a driving part 816b.

The shaft 816a extends horizontally so as to pass through the lid member 815. A sealing member 817 is provided between the shaft 816a and the lid member 815. The sealing member 817 is a member that supports the shaft 816a and seals a space between the shaft 816a and the lid member 815, and is, for example, a magnetic fluid seal. The leading end of the shaft 816a is connected to the base end of the flow path member 813, and the base end of the shaft 816a is connected to the driving part 816b.

The driving part 816b includes, for example, a motor and generates a driving force for rotating the shaft 816a around the central axis X5. As the shaft 816a rotates around the central axis X5, the flow path member 813 rotates around the central axis X5 within the recess 812.

The shaft 816a may be formed integrally with the flow path member 813.

Further, the shaft 816a includes an introduction path 816c for introducing a gas into the flow path 814 of the flow path member 813. The introduction path 816c is connected to the upstream end, that is, the base end, of the flow path 814 of the flow path member 813 arranged inside the recess 812. Further, the introduction path 816c is connected to one end of the pipe 83 via a rotary joint 818. The other end of the pipe 83 is connected to the gas supplier 80 (see FIG. 1). Therefore, a gas from the gas supplier 80 is discharged from the discharge hole 811 corresponding to the orientation of the flow path member 813 toward the susceptor 11 specifically, horizontally) through the pipe 83, the rotary joint 818, the introduction path 816c, and the flow path 814 of the flow path member 813 arranged inside the recess 812.

As described above, each gas discharger 810 is configured to be able to adjust the gas discharge position in the vertical plane in the vertical direction by changing the gas supply path K7. In the present embodiment, changing the gas supply path K7 means changing the orientation of the flow path member 813 in the recess 812, and each gas discharger 810 selectively discharges a gas from the discharge hole 811 corresponding to the orientation of the flow path member 813 in the recess 812.

In the film forming apparatus according to the present embodiment, by changing the orientation of the flow path member 813 in the recess 812, it is possible to adjust the discharge position of the gas from the third gas shower part 800 in the vertical plane in the vertical direction. As a result, it is possible to adjust the distribution of plasma density on the surface of the wafer W in the wafer radial direction. Therefore, according to the present embodiment as well, it is possible to improve the uniformity of film formation in the wafer radial direction in the film formation apparatus using a microwave regardless of the film formation pressure.

### Ninth Embodiment

FIG. 31 is a partially enlarged cross-sectional view for explaining the outline of a gas discharger of a third gas shower part of a film forming apparatus as a plasma processing apparatus according to a ninth embodiment.

Similarly to the third gas shower part 700 according to the seventh embodiment, a third gas shower part 900 shown in FIG. 31 also supplies a gas from the side of the susceptor 11. The third gas shower part 900 also includes a gas discharger 910 that discharges the gas toward the susceptor 11, and a plurality of gas dischargers 910 are provided along the circumferential direction of the ceiling wall 10a in a plan view.

Similarly to the gas discharger 710 according to the seventh embodiment, each gas discharger 910 includes therein a gas supply path K8 that guides a gas to a discharge position, that is, a gas discharge port 911, of the gas from the gas discharger 910. Further, each gas discharger 910 is also configured to be able to adjust the discharge position in the vertical plane in the vertical direction by changing the gas supply path K8.

However, unlike the gas discharger 710 according to the seventh embodiment, each gas discharger 910 includes one gas discharge port 911 provided at a position spaced apart from a predetermined axis (specifically, the central axis X6 of the gas discharger 910) toward the susceptor 11.

Each gas discharger 910 also includes a flow path member 912. The flow path member 912 forms a flow path 913 that communicates with the gas discharge port 911.

The flow path member 912 is configured to be able to change its direction around the predetermined axis. Specifically, the flow path member 912 is attached so as to be rotatable around the central axis X6 and to penetrate through the sidewall 10b. By rotating the flow path member 912 around the central axis X6, that is, by changing the orientation of the flow path member 912, the gas discharge position in the vertical plane in the vertical direction may be adjusted.

Further, each gas discharger 910 includes a lid member 914 that closes a portion of the sidewall 10b through which the flow path member 912 penetrates. A sealing member (not shown) such as an O-ring for sealing the chamber 2 is provided between the lid member 914 and the outer surface of the sidewall 10b.

Further, in each gas discharger 910, the base end of the flow path member 912 is connected to a rotation mechanism 915. The rotation mechanism 915 includes a shaft 915a and a driving part 915b.

The shaft 915a extends horizontally so as to pass through the lid member 914. A sealing member 916 is provided between the shaft 915a and the lid member 914. The sealing member 916 is a member that supports the shaft 915a and seals a space between the shaft 915a and the lid member 914, and is, for example, a magnetic fluid seal. The leading end of the shaft 915a is connected to the base end of the flow path member 912, and the base end of the shaft 915a is connected to the driving part 915b.

The driving part 915b includes, for example, a motor and generates a driving force for rotating the shaft 915a around the central axis X6. As the shaft 915a rotates around the central axis X6, the flow path member 912 rotates around the central axis X6.

The shaft 915a may be formed integrally with the flow path member 912.

Further, the shaft 915a includes an introduction path 915c for introducing a gas into the flow path 913 of the flow path member 912. The introduction path 915c is connected to the upstream end, that is, the base end, of the flow path 913 of the flow path member 912. Further, the introduction path 915c is connected to one end of the pipe 83 via a rotary joint 917. The other end of the pipe 83 is connected to the gas supplier 80 (see FIG. 1). Therefore, a gas from the gas supplier 80 is discharged from the gas discharge port 911 at a position corresponding to the orientation of the flow path member 912 toward the susceptor 11 (specifically, horizontally) through the pipe 83, the rotary joint 917, the introduction path 915c, and the flow path 913 of the flow path member 912.

As described above, each gas discharger 910 is configured to be able to adjust the gas discharge position, that is, the position of the gas discharge port 911, in the vertical plane in the vertical direction by changing the gas supply path K8. In the present embodiment, changing the gas supply path K8 means changing the orientation of the flow path member 912, and each gas discharger 910 discharges a gas from the gas discharge port 911 located at a position corresponding to the orientation of the flow path member 912.

Further, a cover member (not shown) may be provided to cover a portion of the flow path member 912 exposed inside the chamber 2. The cover member may be formed integrally with the sidewall 10b of the chamber 2.

In the film forming apparatus according to the present embodiment, by changing the orientation of the flow path member 912, it is possible to adjust the discharge position of the gas from the third gas shower part 900 in the vertical plane in the vertical direction. As a result, it is possible to adjust the distribution of plasma density on the surface of the wafer W in the wafer radial direction. Therefore, according to the present embodiment as well, it is possible to improve the uniformity of film formation in the wafer radial direction in the film formation apparatus using a microwave regardless of the film formation pressure.

### Modifications

Although the technique according to the present disclosure has been applied to the film forming apparatus in the above, it may also be applied to other plasma processing apparatuses such as an etching apparatus and a cleaning apparatus.

According to the present disclosure in some embodiments, it is possible to improve the uniformity of plasma processing results in a radial direction of a substrate in a plasma processing apparatus that uses a microwave, without changing processing conditions that are not desirable to change.

It should be considered that the embodiments disclosed this time are illustrative in all respects and not restrictive. The above-described embodiments may be omitted, substituted, or modified in various ways without departing from the appended claims and the gist thereof.

What is claimed is:

1. A plasma processing apparatus comprising:
a stage on which a substrate is placed;
a chamber in which the stage is provided;
a plasma source configured to introduce a microwave into the chamber from a ceiling wall of the chamber to generate surface wave plasma inside the chamber; and
at least one gas discharger configured to discharge a gas toward the stage,
wherein the at least one gas discharger is configured to adjust a gas discharge position in a predetermined plane and a distance from a center of the stage to the gas discharge position by changing a gas supply path existing inside the at least one gas discharger.

2. The plasma processing apparatus of claim 1, wherein the at least one gas discharger is configured to selectively discharge the gas from a plurality of discharge positions having different distances from the center of the stage.

3. The plasma processing apparatus of claim 2, wherein the at least one gas discharger includes:
discharge holes provided to correspond to the plurality of discharge positions;
a recess in communication with each of the discharge holes; and
a flow path member arranged inside the recess and configured to form a flow path connected to one of the discharge holes.

4. The plasma processing apparatus of claim 3, wherein the changing the gas supply path changes the flow path member, and
wherein the at least one gas discharger is configured to selectively discharge the gas from the discharge hole corresponding to the flow path member arranged inside the recess.

5. The plasma processing apparatus of claim 3, wherein the plurality of discharge positions and the discharge holes are arranged along a circumferential direction around a predetermined axis toward the stage,
the flow path member is configured to change an orientation around the predetermined axis,
the changing the gas supply path changes the orientation of the flow path member, and
the at least one gas discharger is configured to selectively discharge the gas from the discharge hole corresponding to the orientation of the flow path member.

6. The plasma processing apparatus of claim 1, wherein the at least one gas discharger includes:
a gas discharge port provided at a position spaced apart from a predetermined axis toward the stage; and
a flow path member configured to form a flow path in communication with the gas discharge port,
wherein the flow path member is configured to change an orientation around the predetermined axis, and
the changing the gas supply path changes the orientation of the flow path member.

7. The plasma processing apparatus of claim 4, further comprising: an upper gas supplier configured to supply the gas from the ceiling wall into the chamber.

8. The plasma processing apparatus of claim 7, wherein the upper gas supplier includes the at least one gas discharger.

9. The plasma processing apparatus of claim 8, further comprising: an intermediate gas supplier configured to supply the gas into the chamber at a predetermined height between the ceiling wall and the stage.

10. The plasma processing apparatus of claim 9, wherein the intermediate gas supplier includes the at least one gas discharger.

11. The plasma processing apparatus of claim 10, further comprising: a lateral gas supplier configured to supply the gas into the chamber from a lateral side of the stage.

12. The plasma processing apparatus of claim 11, wherein the lateral gas supplier includes the at least one gas discharger.

13. The plasma processing apparatus of claim 12, wherein the at least one gas discharger includes a plurality of gas dischargers provided along the circumferential direction of the stage.

14. The plasma processing apparatus of claim 13, wherein the ceiling wall of the chamber includes a plurality of dielectric windows for transmitting the microwave therethrough.

15. The plasma processing apparatus of claim 14, wherein the plurality of dielectric windows include a central dielectric window provided in the center of the ceiling wall, and a plurality of outer dielectric windows provided along the circumferential direction around the central dielectric window.

16. The plasma processing apparatus of claim 1, further comprising: an upper gas supplier configured to supply the gas from the ceiling wall into the chamber.

17. The plasma processing apparatus of claim 1, further comprising: an intermediate gas supplier configured to supply the gas into the chamber at a predetermined height between the ceiling wall and the stage.

18. The plasma processing apparatus of claim 1, further comprising: a lateral gas supplier configured to supply the gas into the chamber from a lateral side of the stage.

19. The plasma processing apparatus of claim 1, wherein the at least one gas discharger includes a plurality of gas dischargers provided along the circumferential direction of the stage.

20. A plasma processing apparatus comprising:
a stage on which a substrate is placed;
a chamber inside which the stage is provided;
a plasma source configured to introduce a microwave into the chamber from a ceiling wall of the chamber so as to generate surface wave plasma inside the chamber;
an upper gas supplier configured to supply a gas from the ceiling wall into the chamber; and
an intermediate gas supplier provided to extend from the ceiling wall and configured to supply the gas into the chamber at a predetermined height between the ceiling wall and the stage,
wherein the intermediate gas supplier includes a gas discharger configured to discharge the gas toward the stage, and
the gas discharger is configured to adjust a discharge position of the gas from the gas discharger in a predetermined plane in a radial direction of the stage by changing a gas supply path existing inside the gas discharger.
